(19) United States
(12) Patent Application Publication
(10) Pub. No.: US 2026/0231388 A1
(43) Pub. Date: Aug. 6, 2026

(54) MEMORY DEVICE

(71) Applicant: SEMICONDUCTOR ENERGY LABORATORY CO., LTD., Atsugi-shi, Kanagawa-ken (JP)

(72) Inventors: Hiroki INOUE, Atsugi, Kanagawa (JP); Takanori MATSUZAKI, Atsugi, Kanagawa (JP); Naoto KUSUMOTO, Isehara, Kanagawa (JP)

(21) Appl. No.: 19/123,614

(22) PCT Filed: Nov. 8, 2023
(86) PCT No.: PCT/IB2023/061251

§ 371 Date: Apr. 23, 2025

(30) Foreign Application Priority Data
Nov. 15, 2022 (JP) 2022-182247

(51) Int. Cl. H10B 12/00

(52) U.S. Cl. CPC H10B 12/00

(57) ABSTRACT

A memory device with high reliability of data reading is provided. The memory device includes a first transistor and a second transistor in a memory cell. A vertical transistor that occupies a small area and includes a channel formation region along the side surface of an opening portion provided in an insulating layer is used as each of the two transistors. When the transistors and wirings used in the memory cell have an appropriate structure, the capacitances of parasitic capacitances generated between a data retention node and the wirings can be reduced, so that the reliability of data reading can be improved.

### TECHNICAL FIELD

One embodiment of the present invention relates to a transistor, a semiconductor device, a memory device, and an electronic device. Another embodiment of the present invention relates to a method for manufacturing a memory device or a semiconductor device. Another embodiment of the present invention relates to a semiconductor wafer and a module.

Note that in this specification and the like, a semiconductor device refers to a general device that can function by utilizing semiconductor characteristics. A semiconductor element such as a transistor, a semiconductor circuit, an arithmetic device, and a memory device are each an embodiment of a semiconductor device. It can be sometimes said that a display device (e.g., a liquid crystal display device and a light-emitting display device), a projection device, a lighting device, an electro-optical device, a power storage device, a memory device, a semiconductor circuit, an image capturing device, an electronic device, and the like include a semiconductor device.

One embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

A semiconductor circuit (IC chip) of an LSI, a CPU, a memory, or the like is mounted on a printed wiring board or the like to be used as one of components of a variety of electronic devices. A technique in which a transistor is formed using a semiconductor thin film has attracted attention. The transistor is practically used in an electronic device such as an image display device (also simply referred to as a display device) and is expected to be used in the semiconductor circuit as well.

A silicon-based semiconductor material is widely known as a semiconductor thin film usable for the transistor and further, an oxide semiconductor has been attracting attention as another material. It is known that the current flowing through a transistor including an oxide semiconductor in the non-conducting state (off state) is extremely low.

For example, Patent Document 1 discloses a memory device that can retain stored contents for a long time by utilizing a characteristic of a low leakage current of the transistor including an oxide semiconductor.

In recent years, demand for an integrated circuit with higher density has risen with reductions in size and weight of electronic devices. For example, Patent Document 2 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 3 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2011-151383
[Patent Document 2] PCT International Publication No. 2021/053473
[Patent Document 3] Japanese Published Patent Application No. 2013-211537

### Non-Patent Document

[Non-Patent Document 1] M. Oota et. al, “3D-Stacked CAAC-In-Ga-Zn Oxide FETs with Gate Length of 72 nm”, IEDM Tech. Dig., 2019, pp. 50-53

### SUMMARY OF THE INVENTION

### Problems to be Solved by the Invention

The memory cell disclosed in Patent Document 1 includes a write transistor and a read transistor. The read transistor feeds a current in accordance with the data potential retained in a gate, so that the potential of a bit line (a read line) is changed.

In the memory cell, unlike in a DRAM cell, there is no need to provide a capacitor with a large volume, which enables formation of a memory device (memory) with a high integration degree. By appropriately arranging components included in the memory cell two-dimensionally or three-dimensionally, the integration degree can be further increased, so that a memory device (memory) with a high storage capacity can be formed.

Meanwhile, as miniaturization and high integration of the memory cells progresses, the influence of parasitic capacitance due to overlap of wirings or the like increases. The retained data potential varies by capacitive coupling due to parasitic capacitance to lower the reliability of data reading in some cases.

Thus, an object of one embodiment of the present invention is to provide a memory device with high reliability of data reading. Another object is to provide a memory device that can be highly integrated. Another object is to provide a memory device with favorable electrical characteristics. Another object is to provide a memory device with high reliability. Another object is to provide a memory device with low power consumption. Another object is to provide a novel memory device. Another object is to provide a novel semiconductor device or the like.

Note that the description of these objects does not preclude the existence of other objects. One embodiment of the present invention does not necessarily achieve all these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a memory device including a memory cell, a first wiring, a second wiring, and a third wiring. The memory cell includes a first transistor and a second transistor. The second transistor is provided above the first transistor. The first transistor includes a first semiconductor, a first insulator, and a first conductor. The first semiconductor includes a region formed along a side surface of a first opening portion penetrating through the first wiring, a second insulator, and the second wiring. The first insulator includes a region being in contact with the first semiconductor and covering the first opening portion. The first conductor is provided to be in contact with the first insulator and fill the first opening portion. The second transistor includes a second semiconductor. The second semiconductor includes a region provided along a side surface of a second opening portion penetrating through a third insulator and the third wiring. The second semiconductor includes a region in contact with the first conductor in a bottom portion of the second opening portion.

The second wiring can be provided over the second insulator, and the second insulator can be provided over the first wiring.

The second transistor can include a fourth insulator and a second conductor. The fourth insulator can include a region being in contact with the second semiconductor and covering the second opening portion. The second conductor can be provided to be in contact with the fourth insulator and fill the second opening portion.

The third wiring can be provided over the third insulator, and the third insulator can be provided over the first conductor.

The first wiring can include a region functioning as one of a source electrode and a drain electrode of the first transistor. The second wiring can include a region functioning as the other of the source electrode and the drain electrode of the first transistor. The third wiring can include a region functioning as one of a source electrode and a drain electrode of the second transistor. The first conductor can include a region functioning as a gate electrode of the first transistor and a region functioning as the other of the source electrode and the drain electrode of the second transistor.

Another embodiment of the present invention is a memory device including a memory cell, a first wiring, a second wiring, and a third wiring. The memory cell includes a first transistor and a second transistor. The second transistor is provided above the first transistor. The first transistor includes a first semiconductor, a first insulator, and a first conductor. The first semiconductor includes a region formed along a side surface of a first opening portion penetrating through the first wiring, a second insulator, the second wiring, and a third insulator. The first insulator includes a region being in contact with the first semiconductor and covering the first opening portion. The first conductor is provided to be in contact with the first insulator and fill the first opening portion. The second transistor includes a second semiconductor. The second semiconductor includes a region provided along a side surface of a second opening portion penetrating through a fourth insulator and the third wiring. The second semiconductor includes a region in contact with the first conductor in a bottom portion of the second opening portion.

The third insulator can be provided over the second wiring, the second wiring can be provided over the second insulator, and the second insulator can be provided over the first wiring.

The second transistor can include a fifth insulator and a second conductor. The fifth insulator can include a region being in contact with the second semiconductor and covering the second opening portion. The second conductor can be provided to be in contact with the fifth insulator and fill the second opening portion.

The third wiring can be provided over the fourth insulator, and the fourth insulator can be provided over the first conductor.

The first wiring can include a region functioning as one of a source electrode and a drain electrode of the first transistor. The second wiring can include a region functioning as the other of the source electrode and the drain electrode of the first transistor. The third wiring can include a region functioning as one of a source electrode and a drain electrode of the second transistor. The first conductor can include a region functioning as a gate electrode of the first transistor and a region functioning as the other of the source electrode and the drain electrode of the second transistor.

Another embodiment of the present invention is a memory device including a memory cell, a first wiring, a second wiring, a third wiring, and a fourth wiring. The memory cell includes a first transistor, a second transistor, and a capacitor. The capacitor is provided between the first transistor and the second transistor. The first transistor includes a first semiconductor, a first insulator, and a first conductor. The first semiconductor includes a region formed along a side surface of a first opening portion penetrating through the first wiring, a second insulator, and the second wiring. The first insulator includes a region being in contact with the first semiconductor and covering the first opening portion. The first conductor is provided to be in contact with the first insulator and fill the first opening portion. The capacitor includes a third insulator and a second conductor. The third insulator includes a region formed along a side surface of a second opening portion penetrating through a fourth insulator and the third wiring. The second conductor is provided to be in contact with the third insulator and fill the second opening portion. The second conductor includes a region in contact with the first conductor in a bottom portion of the second opening portion. The second transistor includes a second semiconductor. The second semiconductor includes a region provided along a side surface of a third opening portion penetrating through a fifth insulator and the fourth wiring. The second semiconductor includes a region in contact with the second conductor in a bottom portion of the third opening portion.

The second wiring can be provided over the second insulator, the second insulator can be provided over the first wiring, and the third wiring can be provided over the fourth insulator.

The second transistor can include a sixth insulator and a third conductor. The sixth insulator can include a region being in contact with the second semiconductor and covering the third opening portion. The third conductor can be provided to be in contact with the sixth insulator and fill the third opening portion.

The fourth wiring can be provided over the fifth insulator, and the fifth insulator can be provided over the second conductor.

The first wiring can include a region functioning as one of a source electrode and a drain electrode of the first transistor. The second wiring can include a region functioning as the other of the source electrode and the drain electrode of the first transistor. The third wiring can include a region functioning as one electrode of the capacitor. The fourth wiring include a region functioning as one of a source electrode and a drain electrode of the second transistor. The first conductor can include a region functioning as a gate electrode of the first transistor. The second conductor can include a region functioning as the other electrode of the capacitor and a region functioning as the other of the source electrode and the drain electrode of the second transistor.

In the above memory devices, each of the first semiconductor and the second semiconductor is preferably an oxide semiconductor. The oxide semiconductor preferably contains any one or more selected from In, Ga, and Zn.

### EFFECT OF THE INVENTION

According to one embodiment of the present invention, a memory device with high reliability of data reading can be provided. A memory device that can be highly integrated can be provided. A memory device with favorable electrical characteristics can be provided. A memory device with high reliability can be provided. A memory device with low power consumption can be provided. A novel memory device can be provided. A novel semiconductor device or the like can be provided.

Note that the description of these effects does not preclude the existence of other effects. Note that one embodiment of the present invention does not need to have all of these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1 is a diagram illustrating a memory device.

FIG. 2A to FIG. 2C are circuit diagrams illustrating a memory cell.

FIG. 3 is a timing chart showing operation of a memory cell.

FIG. 4 is a timing chart showing operation of a memory cell.

FIG. 5 is a timing chart showing operation of a memory cell.

FIG. 6A and FIG. 6B are perspective views illustrating a memory cell.

FIG. 7A and FIG. 7B are top views for illustrating a memory cell. FIG. 7C to FIG. 7E are cross-sectional views illustrating the memory cell.

FIG. 8A is a perspective view illustrating a memory cell. FIG. 8B and FIG. 8C are cross-sectional views illustrating the memory cell.

FIG. 9A is a diagram illustrating a memory cell. FIG. 9B and FIG. 9C are cross-sectional views illustrating the memory cell.

FIG. 10A is a cross-sectional perspective view illustrating a memory cell. FIG. 10B and FIG. 10C are cross-sectional views illustrating the memory cell.

FIG. 11A and FIG. 11B are perspective views illustrating a memory cell.

FIG. 12A is a cross-sectional perspective view illustrating a memory cell. FIG. 12B and FIG. 12C are cross-sectional views illustrating a memory cell.

FIG. 13A and FIG. 13B are perspective views illustrating a memory cell.

FIG. 14A and FIG. 14B are diagrams illustrating a transistor.

FIG. 15A and FIG. 15B are diagrams illustrating a structure example of a memory device.

FIG. 16A and FIG. 16B are diagrams illustrating examples of electronic components.

FIG. 17A and FIG. 17B are diagrams illustrating examples of electronic devices. FIG. 17C to FIG. 17E are diagrams illustrating an example of a large computer.

FIG. 18 is a diagram illustrating an example of space equipment.

FIG. 19 is a diagram illustrating an example of a storage system that can be used in a data center.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

In this specification and the like, an oxynitride is a material that contains more oxygen than nitrogen in its composition. Examples of the oxynitride include silicon oxynitride, aluminum oxynitride, and hafnium oxynitride. Moreover, a nitride oxide is a material that contains more nitrogen than oxygen in its composition. Examples of the nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°. The term “orthogonal” indicates that two straight lines intersect or are connected to each other at an angle greater than or equal to 80° and less than or equal to 100°. Thus, the case where the angle is greater than or equal to 85° and less than or equal to 95° is also included. The terms “approximately orthogonal” and “substantially orthogonal” indicate that two straight lines intersect or are connected to each other at an angle greater than or equal to 60° and less than or equal to 120°.

In the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

Moreover, in this specification and the like, terms for describing arrangement, such as “over” and “under”, are used for convenience for describing the positional relationship between components with reference to drawings. The positional relation between components is changed as appropriate in accordance with the direction in which the components are described. Thus, without limitation to terms described in this specification, the description can be changed appropriately depending on the situation.

### Embodiment 1

In this embodiment, a memory device of one embodiment of the present invention is described. The memory device of one embodiment of the present invention includes a first transistor and a second transistor in a memory cell.

As the two transistors, vertical transistors each of which includes a channel formation region along a side surface of an opening portion provided in an insulator are used. The vertical transistor can have a structure with a short channel length and a wide channel width, thereby having a high on-state current. The area occupied by the vertical transistors can be small in a top view. Accordingly, the use of a vertical transistor in a memory cell enables formation of a memory device that can operate at high speed and has a high integration degree.

A plurality of wirings are connected to the memory cell, and parasitic capacitance is generated between a data retention portion of the memory cell and each of the wirings. Along with change of wiring potential, capacitive coupling due to the parasitic capacitance may vary the potential of the data retention portion to impair the reliability of data reading. In the memory device of one embodiment of the present invention, the capacitance of the parasitic capacitance can be reduced with an appropriate structure of the memory cell, and thus the reliability of data reading can be improved.

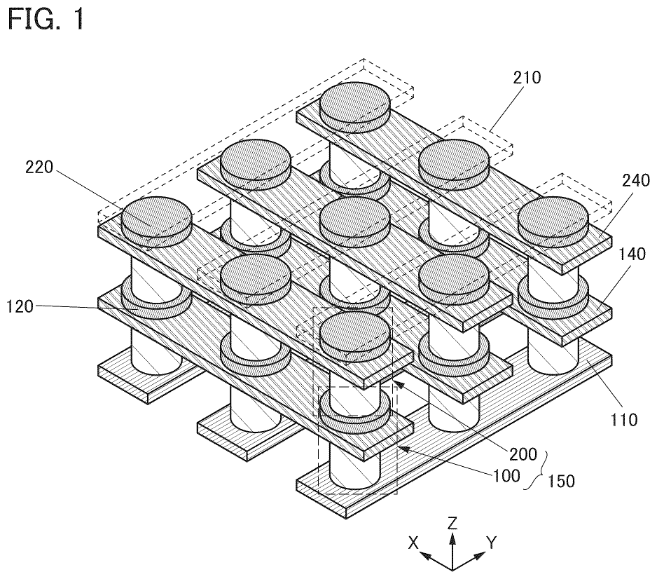

FIG. 1 is a perspective view illustrating part of the memory device of one embodiment of the present invention and illustrates a plurality of memory cells 150 (a transistor 100 and a transistor 200). The transistor 100 and the transistor 200 are vertical transistors and the transistor 200 is provided above the transistor 100. The memory cell 150 is electrically connected to a wiring 110, a wiring 140, a wiring 240, and a wiring 210. Note that for clarity, in FIG. 1, insulators such as interlayer films are not illustrated, and the uppermost wirings 210 are illustrated by dashed lines.

The transistor 100 includes the wiring 110, the wiring 140, and a conductor 120 as its components. The transistor 200 includes the conductor 120, the wiring 240, and a conductor 220 as its components.

The wiring 110 includes a region functioning as one of a source electrode and a drain electrode of the transistor 100. The wiring 140 includes a region functioning as the other of the source electrode and the drain electrode of the transistor 100.

The conductor 120 includes a region functioning as a gate electrode of the transistor 100 and a region functioning as one of a source electrode and a drain electrode of the transistor 200. In other words, the conductor 120 includes a region shared by the gate electrode of the transistor 100 and the one of the source electrode and the drain electrode of the transistor 200.

The wiring 240 includes a region functioning as the other of the source electrode and the drain electrode of the transistor 200.

The conductor 220 includes a region functioning as a gate electrode of the transistor 200 and is electrically connected to the wiring 210 formed over the conductor 220. Note that the conductor 220 and the wiring 210 may be formed as one component. The structures and connection modes of the transistors are described in detail later.

Although FIG. 1 illustrates an example in which the memory cells 150 are arranged at regular intervals in the X direction and the Y direction, a staggered arrangement in which the memory cells 150 are alternately staggered one by one may be employed.

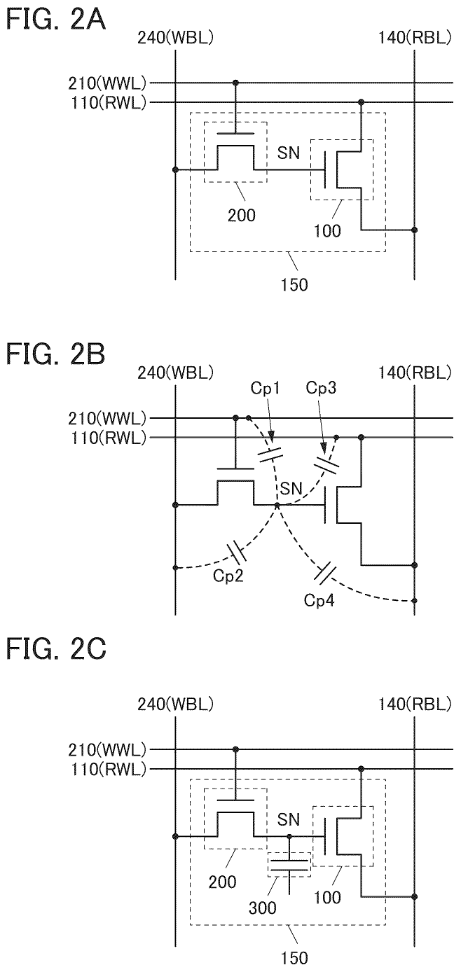

FIG. 2A is a diagram illustrating an example of a circuit diagram of the memory cell 150. The transistor 100 has a function of reading data. The transistor 200 has a function of writing data.

One of a source and a drain of the transistor 200 is electrically connected to a gate of the transistor 100. The conductor 120 serves this connection structure in FIG. 1. The conductor 120 can also be referred to as a component of a node SN that retains a data potential in the memory cell 150 illustrated in FIG. 2A.

The wiring 210 connected to the gate of the transistor 200 is a wiring that supplies a write word signal to the memory cell 150 and also referred to as a write word line (WWL). The write word signal is a signal that controls the timing of data writing to the memory cell 150.

The wiring 240 connected to the other of the source and the drain of the transistor 200 is a wiring that supplies a potential corresponding to a data signal (data) to the memory cell 150 and also referred to as a write bit line (WBL). The data signal is a signal written to the memory cell 150 and represented by two values which are a high-level (also referred to as “1” or V_{H}) and a low-level (also referred to as “0” or V_{L}).

The wiring 110 connected to the one of the source and the drain of the transistor 100 is a wiring that supplies a read word signal to the memory cell 150 and also referred to as a read word line (RWL). The read word signal is a signal that controls the timing of data reading from the memory cell 150.

The wiring 140 connected to the other of the source and the drain of the transistor 100 is a wiring for reading a potential corresponding to a data signal (data) retained in the memory cell 150 and also referred to as a read bit line (RBL). A current flows through the transistor 100 in accordance with the data (“1” or “0”) written to the memory cell 150, so that the potential of the precharged wiring 140 is changed. The potential is input to a sense amplifier, whereby data can be read.

Here, parasitic capacitance generated between the node SN and each wiring is described. As illustrated in FIG. 1, when the focus is placed on the conductor 120, which is the component of the node SN, an insulator that is not illustrated is provided between the conductor 120 and each wiring, which means that a plurality of parasitic capacitances are formed.

Here, for simple description, parasitic capacitance generated between the node SN and one wiring is collectively described as one parasitic capacitance. As illustrated in FIG. 2B, parasitic capacitance Cp1 is generated between the node SN and the wiring 210. Parasitic capacitance Cp2 is generated between the node SN and the wiring 240. Parasitic capacitance Cp3 is generated between the node SN and the wiring 110. Parasitic capacitance Cp4 is generated between the node SN and the wiring 140. Note that a component of the transistor 100 or the transistor 200 are also included in the components of the parasitic capacitances.

Since the node SN is floating, when the potentials of wirings vary, the potential of the node SN also varies by capacitive coupling by the influence of any one or more of the parasitic capacitances Cp1 to Cp4. The range of potential variation of the node SN depends on the amounts of potential variation of wirings and the capacitances of parasitic capacitances; however, when the potential variation of the node SN is too large, the transistor 100 does not operate normally and thus data cannot be read accurately in some cases.

As a countermeasure against the influence of the parasitic capacitance, as illustrated in FIG. 2C, a capacitor 300 whose one electrode is connected to the one of the source and the drain of the transistor 200 and the gate of the transistor 100 can be provided. The other electrode of the capacitor 300 is connected to a wiring to which a fixed potential is supplied. In the case where the capacitor 300 is provided, the potential variation in the node SN due to parasitic capacitance can be inhibited to be small and the reading accuracy can be increased. Furthermore, the data retention capability can be increased.

Note that one embodiment of the present invention can be applied to both of the circuit structure illustrated in FIG. 2A and the circuit structure illustrated in FIG. 2C.

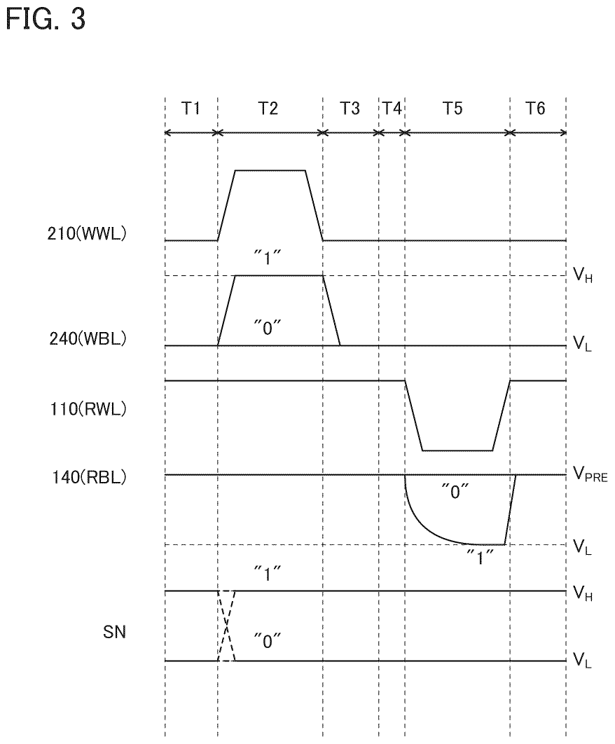

Next, the operation of the memory cell 150 will be described with reference to FIG. 3. Here, an ideal operation where the influence of parasitic capacitances is eliminated is described. FIG. 3 is a timing chart for showing an operation example of the memory cell 150 illustrated in FIG. 2A.

In FIG. 3, the potentials supplied to the wiring 210 (WWL), the wiring 240 (WBL), and the wiring 110 (RWL), the potential read to the wiring 140 (RBL), and the potential of the node SN are illustrated. Note that in FIG. 3, the wiring 240 (WBL) is set to the low level (V_{L}) in the standby state.

Period T1 is a standby period. Period T2 is a write period. Period T3 is a standby period. Periods T4 to T5 are read periods. Period T6 is a standby period. Note that FIG. 3 illustrates data “1” or “0” written to the memory cell 150 (the node SN) through the wiring 240 (WBL). The data written to the memory cell 150 is data “1” when the wiring 240 is set to the high level and is data “0” when the wiring 240 is set to the low level.

FIG. 3 illustrates data “1” or “0” read from the memory cell 150 through the wiring 140 (RBL). The wiring 140 (RBL) is precharged to a high-level potential (e.g., a high power supply potential such as VDD) in the read period, and data is read to an external read circuit connected to the wiring 140 (RBL) in accordance with a change in the precharged potential.

When the data retained in the memory cell 150 (the node SN) is data “1”, a large amount of current flows through the transistor 100, whereby the potential of the wiring 140 (RBL) is lowered. When the data retained in the memory cell 150 (the node SN) is data “0”, a small amount of current flows through the transistor 100, whereby a variation in the potential of the wiring 140 (RBL) is small. That is, when the data retained in the memory cell 150 (the node SN) is data “1”, the potential of the wiring 140 (RBL) turns to the low level. When the data retained in the memory cell 150 (the node SN) is data “0”, the potential of the wiring 140 (RBL) turns to the high level (the precharged potential).

In Period T1, the wiring 210 (WWL) is at the low level, the wiring 240 (WBL) is at the low level (V_{L}), the wiring 110 (RWL) is at the high level, and the wiring 140 (RBL) is at the high level. At this time, the transistor 200 is in the non-conducting state. A current does not flow through the transistor 100 since the potentials of the terminals serving as the source and the drain are equal to each other. Note that the potential of the gate of the transistor 100 (the node SN) is the potential V_{H} or V_{L} written in the previous write period.

In Period T2, the wiring 210 (WWL) is at the high level, the wiring 240 (WBL) is the signal corresponding to data (V_{H} or V_{L}), the wiring 110 (RWL) is at the high level, and the wiring 140 (RBL) is at the high level. At this time, the transistor 200 is in the conducting state, and the potential of the gate of the transistor 100 (the node SN) becomes a potential corresponding to the data. A current does not flow through the transistor 100 regardless of the potential of the gate since the potentials of the terminals serving as the source and the drain are equal to each other.

In Period T3, the wiring 210 (WWL) is at the low level, the wiring 240 (WBL) is at the low level (V_{L}), the wiring 110 (RWL) is at the high level, and the wiring 140 (RBL) is at the high level. At this time, the transistor 100 and the transistor 200 are both in the non-conducting state. In Period T3, the potential written to the gate of the transistor 100 (the node SN) is retained. A current does not flow through the transistor 100 regardless of the potential of the gate since the potentials of the terminals serving as the source and the drain are equal to each other.

In Period T4, the wiring 210 (WWL) is at the low level, the wiring 240 (WBL) is at the low level (V_{L}), and the wiring 110 (RWL) is at the high level. The wiring 140 (RBL) is precharged to the high level (also referred to as a precharge potential V_{PRE}). At this time, the transistor 200 is in the non-conducting state. The precharged voltage V_{PRE} is, for example, VDD and is equal to the high level of the wiring 140 (RBL). A current does not flow through the transistor 100 regardless of the potential of the gate (the node SN) since the potentials of the terminals serving as the source and the drain are equal to each other. In other words, the potential of the wiring 140 does not change.

In Period T5, the wiring 210 (WWL) is at the low level, the wiring 240 (WBL) is at the low level (V_{L}), and the wiring 110 (RWL) is at the low level. At this time, the transistor 200 is in the non-conducting state. In Period T5, the wiring 140 (RBL) is brought into an electrically floating state. That is, the potential varies in accordance with the current flowing through the transistor 100 in the memory cell 150.

In the period T5, a potential difference occurs between the terminals serving as the source and the drain of the transistor 100, and a current flows through the transistor 100 in accordance with the potential of the gate (the node SN). In the case where data “1” is retained in the memory cell 150, a large current flows through the transistor 100 and the potential of the wiring 140 (RBL) is lowered to the low level. By this change in the potential of the wiring 140 (RBL), a sense amplifier connected to the wiring 140 (RBL) can be activated and the data in the selected memory cell 150 can be read to the outside.

In the case where data “0” is retained in the memory cell 150, a small current flows through the transistor 100 and the potential of the wiring 140 (RBL) changes little from the high-level potential (the precharged potential).

In the memory cell 150 in a non-selected row in the period T5, the wiring 110 (RWL) is at the high level and a current does not flow through the transistor 100 regardless of the potential of the gate since the potentials of the terminals serving as the source and the drain are equal.

In Period T6, the wiring 210 (WWL) is at the low level, the wiring 240 (WBL) is at the low level (V_{L}), the wiring 110 (RWL) is at the high level, and the wiring 140 (RBL) is at the high level. At this time, the transistor 200 is in the non-conducting state. A current does not flow through the transistor 100 regardless of the potential of the gate since the potentials of the terminals serving as the source and the drain are equal.

Through the above operations, data can be read from the memory cell 150 in the selected row.

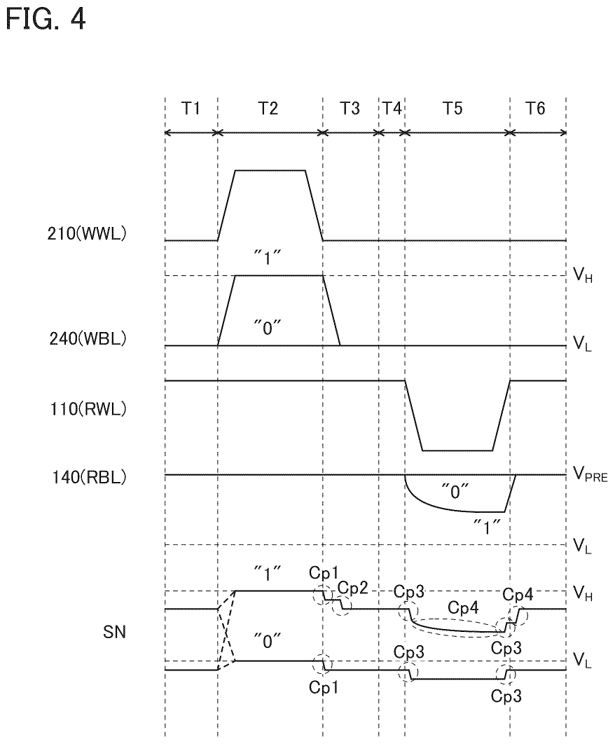

Next, the influence of the parasitic capacitances Cp1 to Cp4 in the operation similar to that in FIG. 3 is described with reference to a timing chart shown in FIG. 4. Note that the capacitances of the parasitic capacitances Cp1 to Cp4 are actually different from each other, but are regarded as substantially the same here. The behavior of the potential variation of the node SN due to the parasitic capacitance shown in FIG. 4 is an example and may have slight differences from the actual behavior, such as the degree of variation and deviation in the timing.

The operation up to writing data to the node SN in Period T2 is similar to that in FIG. 3. Note that the potential of the node SN in Period T1 is a potential corresponding to the potential written in the previous writing period.

When the wiring 210 (WWL) is at the high level in Period T2, the potential of the node SN is a potential corresponding to data supplied to the wiring 240 (WBL) (“1” (V_{H}) or “0” (V_{L})).

Then, when the wiring 210 (WWL) is switched to the low level in Period T3, the potential of the node SN is lowered by capacitive coupling due to the parasitic capacitance Cp1 (the parasitic capacitance between the node SN and the wiring 210 (WWL)).

Furthermore, in the case of data “1”, since the wiring 240 (WWL) is lowered to the low level (V_{L}) in Period T3, the potential of the node SN corresponding to data “1” is further lowered by capacitive coupling due to the parasitic capacitance Cp2 (the parasitic capacitance between the node SN and the wiring 240 (WBL)). Note that in the case of data “0”, the potential of the wiring 240 (WWL) does not change and thus the potential of the node SN also does not change.

In Period T5, when the potential of the wiring 110 (RWL) is switched from the high level to the low level, the potential of the node SN is lowered by capacitive coupling due to the parasitic capacitance Cp3 (the parasitic capacitance between the node SN and the wiring 110 (WWL)).

Furthermore, in the case of data “1”, the wiring 140 (RBL) is lowered to be closer to the low level (V_{L}); thus, the potential of the node SN corresponding to data “1” is gradually lowered by capacitive coupling due to the parasitic capacitance Cp4 (the parasitic capacitance between the node SN and the wiring 140 (WBL)). Note that in the case of data “0”, the potential of the wiring 140 (WWL) does not change and thus the potential of the node SN also does not change.

Furthermore, when the potential of the wiring 110 (RWL) is switched to the high level, the potential of the node SN is increased by capacitive coupling due to the parasitic capacitance Cp3.

In the case of data “1”, when the wiring 140 (RBL) turns to the high level, the potential of the node SN corresponding to data “1” increases by capacitive coupling due to the parasitic capacitance Cp4. Note that in the case of data “0”, the potential of the wiring 140 (WWL) does not change and thus the potential of the node SN does not change.

As described above, the potential of the node SN varies by the influence of the parasitic capacitances Cp1 to Cp4. In particular, in the case where data “1” is written, the potential of the node SN is lowered by the influence of all of the parasitic capacitances Cp1 to Cp4 before data reading; thus, the reliability of the read data is degraded in some cases.

Note that although the wiring 240 (WBL) is set to the low level (V_{L}) in the standby state in FIG. 4, the wiring 240 can be set to the high level (V_{H}) in the standby state to avoid the influence of some parasitic capacitance.

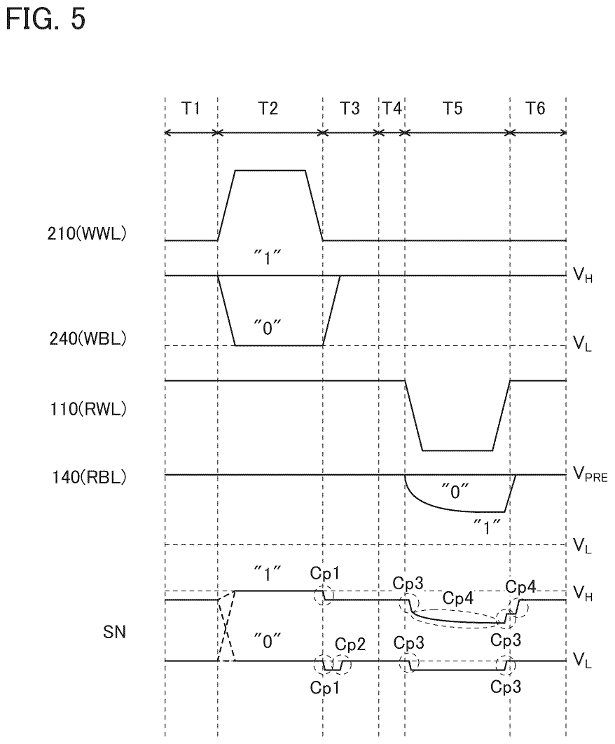

FIG. 5 is a timing chart of the case where the wiring 240 (WBL) is set to the high level (V_{H}) in the standby state.

The operation until the potential of the node SN is lowered by capacitive coupling due to the parasitic capacitance Cp1 at the beginning of Period T3 is the same as that in FIG. 4.

In the case of data “1”, the potential of the wiring 240 (WWL) does not change and thus the potential of the node SN does not change in Period T3. In the case of data “0”, the wiring 240 (WWL) is switched to the high level (V_{H}), and thus the potential of the node SN corresponding to data “0” increases by capacitive coupling due to the parasitic capacitance Cp2.

Here, in the case of data “0”, the potential of the node SN is previously lowered by capacitive coupling due to the parasitic capacitance Cp1; thus, capacitive coupling due to the parasitic capacitance Cp2 acts in the direction of canceling the decrease in the potential due to the parasitic capacitance Cp1.

Subsequent potential variation of the node SN due to the parasitic capacitance is the same as that in FIG. 4. Accordingly, when the wiring 240 (WBL) is set to the high level (V_{H}) in the standby state, potential variation of the node SN can be reduced.

In the case of data “1”, the potential is affected by the parasitic capacitances Cp1, Cp3, and Cp4 before data reading. In the case of data “0”, the potential is affected by the parasitic capacitances Cp1, Cp2, and Cp3 before data reading. Note that in the case of data “0”, the potential can be regarded as being affected by only the parasitic capacitance Cp3 because the potential variations of the node SN due to the parasitic capacitance Cp1 and the parasitic capacitance Cp2 act to cancel each other.

Thus, regardless of data “1” or data “0”, it can be said that the parasitic capacitance that most affects the potential variation of the node SN is the parasitic capacitance Cp3, and thus the capacitance of the parasitic capacitance Cp3 is preferably small. In addition, in order to reduce the influence in reading data “1”, the capacitance of the parasitic capacitance Cp4 is also preferably small.

### Structure Example 1 of Memory Cell

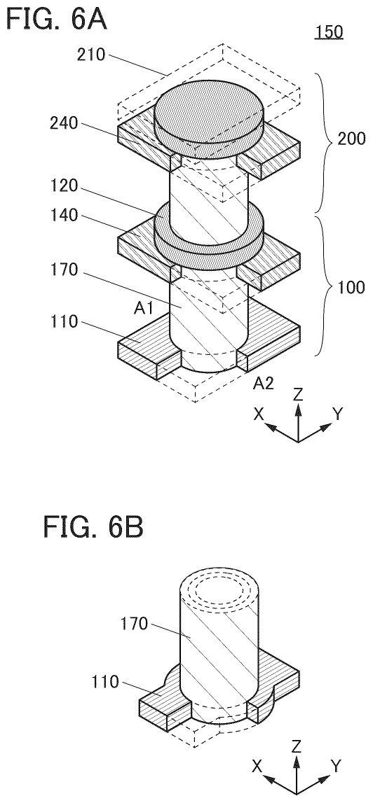

Next, a structure example of the memory cell 150 is described. FIG. 6A is a perspective view illustrating Structure example 1 of the memory cell 150. Note that for clarity, an insulator such as an interlayer film is not illustrated, and the wiring 210 and part of the wiring 110, the wiring 140, and the wiring 240 are illustrated by dashed lines.

In the transistor 100 in the memory cell 150 illustrated in FIG. 6A, a semiconductor layer (an oxide semiconductor 170) is provided in an opening portion provided in the wiring 110, and the side surface of the wiring 110 in the opening portion is in contact with the semiconductor layer.

Although FIG. 6A illustrates an example in which the width of the wiring 110 is constant in the longitudinal direction, the width of the wiring 110 may be increased in the vicinity of the opening portion as illustrated in FIG. 6B. The same structure can be applied to the wiring 140 and the wiring 240.

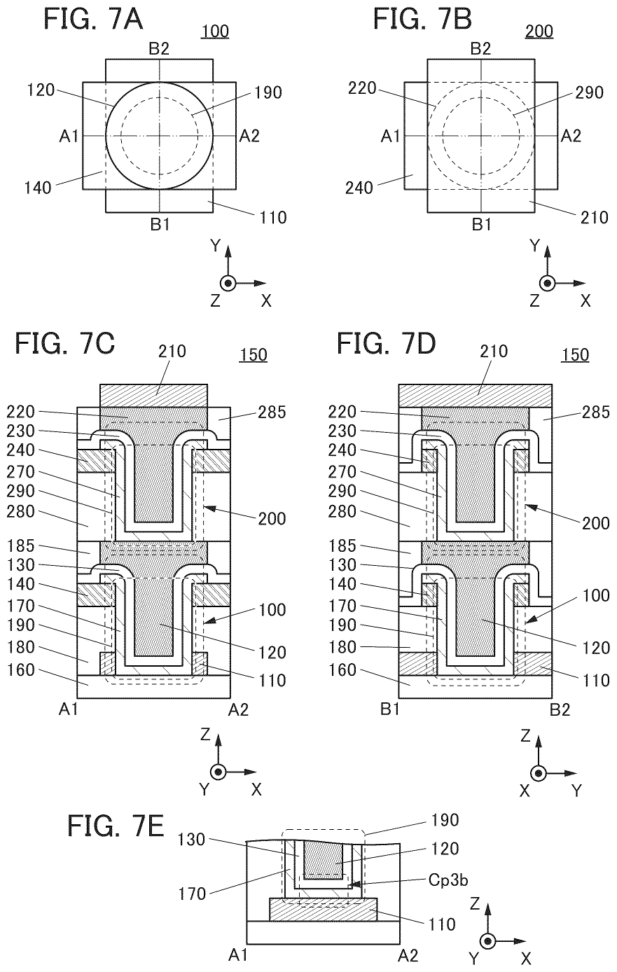

FIG. 7A is a top view illustrating the transistor 100, and FIG. 7B is a top view illustrating the transistor 200. Note that for clarity, some components are not illustrated in the top views. The top views illustrated in FIG. 7A and FIG. 7B are common to other structure examples of the memory cell 150 described in this embodiment.

FIG. 7C is a diagram corresponding to the cross section along the line A1-A2 in FIG. 7A and FIG. 7B. FIG. 7D is a diagram corresponding to the cross section along the line B1-B2 in FIG. 7A and FIG. 7B.

The memory cell 150 includes an insulator 160 over a substrate (not illustrated), the transistor 100 over the insulator 160, and the transistor 200 over the transistor 100. Between the transistors and wirings, an insulator 180, an insulator 185, an insulator 280, an insulator 285, and the like functioning as interlayer films can be provided.

The transistor 100 includes the oxide semiconductor 170, an insulator 130, and the conductor 120. The oxide semiconductor 170 functions as a semiconductor layer, the insulator 130 functions as a gate insulator, and the conductor 120 functions as the gate electrode. The wiring 110 includes a region that functions as the one of the source electrode and the drain electrode of the transistor 100. The wiring 140 includes a region that functions as the other of the source electrode and the drain electrode of the transistor 100.

An opening portion 190 penetrating through the wiring 140, the insulator 180, and the wiring 110 and reaching the insulator 160 is provided. The opening portion 190 has a pillar shape with a substantially circular top surface. With such a structure, the memory cell can be miniaturized and highly integrated. Note that the side surface of the opening portion 190 is preferably perpendicular to the top surface of the insulator 160.

At least part of the oxide semiconductor 170 is placed in the opening portion 190. Note that the oxide semiconductor 170 includes a region in contact with the side surface of the wiring 110, a region in contact with the side surface of the wiring 140, a region in contact with the top surface of the insulator 160, and a region in contact with the side surface of the insulator 180 in the opening portion 190.

The insulator 130 is placed so as to at least partly cover the opening portion 190. The conductor 120 is placed such that at least part of the conductor 120 is positioned in the opening portion 190. The conductor 120 is preferably provided so as to be embedded in the opening portion 190, and the top surface shape of the conductor 120 is preferably substantially circular for a higher integration degree.

With such a structure, the capacitance of the parasitic capacitance Cp3 between the conductor 120 (the node SN) and the wiring 110 can be reduced.

As illustrated in FIG. 7E, in the case where the opening portion 190 is not formed in the wiring 110, the top surface of the wiring 110 is exposed in the bottom portion of the opening portion 190. Accordingly, parasitic capacitance Cp3b in which one region of the conductor 120 serves as one electrode, one region of the insulator 130 serves as a dielectric, and one region of the wiring 110 facing the bottom surface of the conductor 120 serves the other electrode is generated in the vicinity of the bottom portion of the opening portion 190. In this case, the oxide semiconductor 170 functions as one or both of a dielectric and the other electrode.

The opening portion 190 is provided to cut out the wiring 110 in one embodiment of the present invention; this enables a state without the one region of the wiring 110 facing the bottom surface of the conductor 120. This corresponds to a reduction in C by reducing the value of an electrode area S (to 0) in the capacitance C=ε×S/d (ε: dielectric constant, S: electrode area, and d: thickness of the dielectric).

In the region where the parasitic capacitance Cp3b is formed in FIG. 7E, the value of the thickness d of the dielectric is small, and the parasitic capacitance Cp3b is a relatively large capacitance. The parasitic capacitance Cp3b is part of the parasitic capacitance Cp3, and thus the capacitance of the parasitic capacitance Cp3 can be reduced by employing the structure where the parasitic capacitance Cp3b is not formed.

Note that since one region of the oxide semiconductor 170 facing the bottom surface of the conductor 120 is not in contact with an element causing n-type conductivity (e.g., the wiring 110), the region has i-type (intrinsic) conductivity and high resistance. Thus, it can be said that the one region of the oxide semiconductor 170 facing the bottom surface of the conductor 120 is less likely to be a component of parasitic capacitance (the other electrode).

The transistor 200 includes an oxide semiconductor 270, an insulator 230, and the conductor 220. The oxide semiconductor 270 functions as a semiconductor layer, the insulator 230 functions as a gate insulator, and the conductor 220 functions as the gate electrode. The conductor 120 includes a region that functions as the one of the source electrode and the drain electrode of the transistor 200. The wiring 240 includes a region that functions as the other of the source electrode and the drain electrode of the transistor 200.

An opening portion 290 penetrating through the wiring 240 and the insulator 280 and reaching the conductor 120 is provided. The opening portion 290 has a pillar shape with a substantially circular top surface. With such a structure, the memory cell can be miniaturized and highly integrated. Note that the side surface of the opening portion 290 is preferably perpendicular to the top surface of the conductor 120.

At least part of the oxide semiconductor 270 is placed in the opening portion 290. The oxide semiconductor 270 includes a region in contact with the top surface of the conductor 120, a region in contact with the side surface of the wiring 240, and a region in contact with the side surface of the insulator 280 in the opening portion 290.

The insulator 230 is placed so as to at least partly cover the opening portion 290. The conductor 220 is placed so that at least part of the conductor 220 is positioned in the opening portion 290. The conductor 220 is preferably provided so as to be embedded in the opening portion 290, and the top surface shape of the conductor 220 is preferably substantially circular for a higher integration degree. The wiring 210 is placed over the conductor 220. Note that the conductor 220 and the wiring 210 may be formed as the same component.

It is preferable that the diameter of the opening portion 190 and the diameter of the opening portion 290 be substantially the same and the opening portion 190 and the opening portion 290 be provided so as to overlap with each other. Furthermore, in the memory cell 150, it is preferable that the width of the wiring 110 and the width of the wiring 210 be substantially the same and the wirings 110 and 210 be provided so as to overlap with each other. Moreover, in the memory cell 150, it is preferable that the width of the wiring 140 and the width of the wiring 240 be substantially the same and the wiring 140 and the wiring 240 be provided so as to overlap with each other.

With this structure, two transistors can be provided without a significant increase of the cell area, whereby the memory cells 150 can be arranged at high density and the memory device can have a large storage capacity. In other words, the memory device can be highly integrated.

Furthermore, the one of the source electrode and the drain electrode of the transistor 200 and the gate electrode of the transistor 100 share the same region; in other words, the transistor 200 and the transistor 100 are directly connected without a wiring or the like therebetween. Accordingly, electric resistance between the transistors can be minimum and data writing or the like can be performed quickly.

### Structure Example 2 of Memory Cell

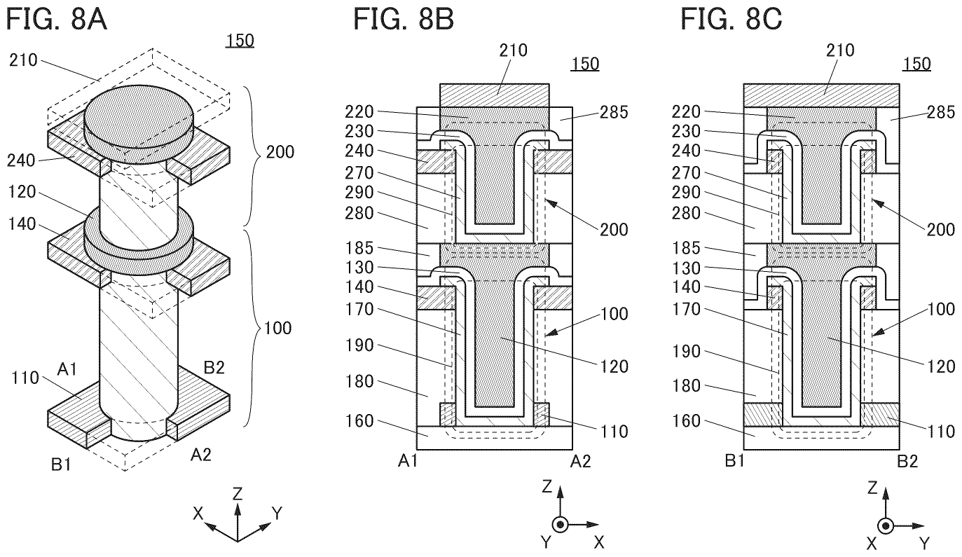

Next, Structure example 2 of the memory cell 150 is described. FIG. 8A is a perspective view illustrating Structure example 2 of the memory cell 150. Note that for clarity, an insulator such as an interlayer film is not illustrated, and the wiring 210 and part of the wiring 110, the wiring 140, and the wiring 240 are illustrated by dashed lines.

FIG. 8B is a diagram corresponding to the cross section along the line A1-A2 in FIG. 7A and FIG. 7B. FIG. 8C is a diagram corresponding to the cross section along the line B1-B2 in FIG. 7A and FIG. 7B. Note that the description of the components that is in common with Structure example 1 is omitted.

Structure example 2 is a structure in which the opening portion 190 is formed in the wiring 110 as in Structure example 1 and the capacitance of parasitic capacitance generated between the upper portion of the conductor 120 and the wiring 110 is further reduced.

Since the conductor 120 is formed to fill the opening portion 190, the diameter of the upper portion of the conductor 120 is preferably larger than the diameter of the opening portion 190. The conductor 120 also functions as one of the source electrode and the drain electrode of the transistor 200 and thus preferably has a large contact area with the oxide semiconductor 270. That is, the diameter of the upper portion of the conductor 120 is preferably larger than the diameter of the opening portion 290.

Thus, the upper portion of the conductor 120 is a factor that increases the capacitance of parasitic capacitance generated between the upper portion of the conductor 120 and another wiring. In Structure example 2, the insulator 180 is made thick and the value of the depth of the opening portion 190 is made large in the transistor 100.

Although Structure example 1 shows the structure where the opening portion 190 and the opening portion 290 are substantially the same, Structure example 2 shows the structure where the value of the depth of the opening portion 190 is larger than that of the opening portion 290. Increasing the value of the depth of the opening portion 190 corresponds to increasing the channel length in a vertical transistor, and thus is effective in the case where the transistor 100 has sufficiently high on-state current characteristics.

With such a structure, the distance between the wiring 110 and the upper portion of the conductor 120 can be physically increased, and the capacitance of the parasitic capacitance Cp3 formed between the wiring 110 and the conductor 120 (the node SN) and serving the insulator 180 and the like as a dielectric can be reduced. This corresponds to a reduction in C by increasing the value of the thickness d of the dielectric in the capacitance C=ε×S/d.

### Structure Example 3 of Memory Cell

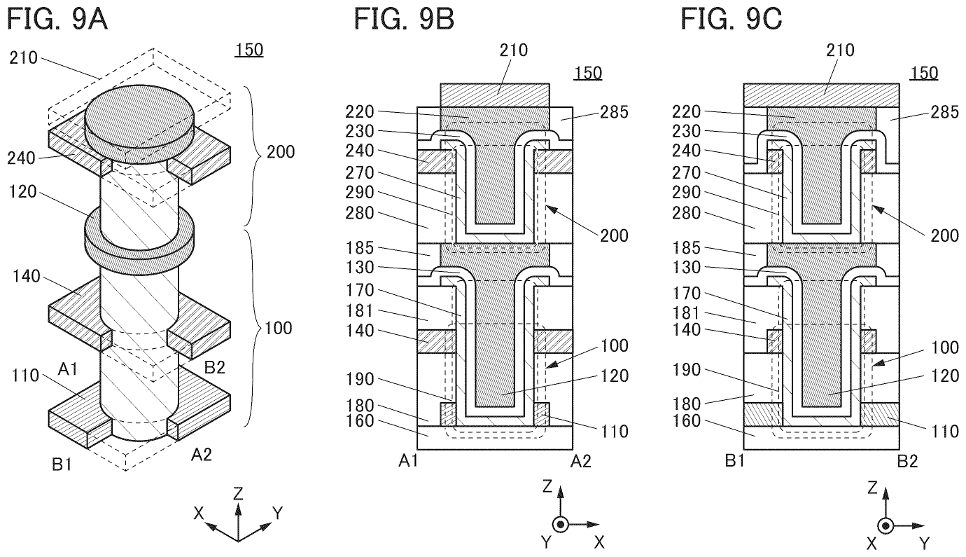

Next, Structure example 3 of the memory cell 150 is described. FIG. 9A is a perspective view illustrating Structure example 3 of the memory cell 150. Note that for clarity, an insulator such as an interlayer film is not illustrated, and the wiring 210 and part of the wiring 140 and the wiring 240 are illustrated by dashed lines.

FIG. 9B is a diagram corresponding to the cross section along the line A1-A2 in FIG. 7A and FIG. 7B. FIG. 9C is a diagram corresponding to the cross section along the line B1-B2 in FIG. 7A and FIG. 7B. Note that the description of the components that is in common with Structure example 1 is omitted.

Structure example 3 is a structure in which the opening portion 190 is formed in the wiring 110 as in Structure example 1, the value of the depth of the opening portion 190 is increased by provision of an insulator 181, and the capacitance of parasitic capacitance generated between the upper portion of the conductor 120 and the wiring 140 is further reduced. In Structure example 3, the insulator 181 is formed over the wiring 140, and the opening portion 190 is formed to penetrate through the insulator 181, the wiring 140, the insulator 180, and the wiring 110 and reach the insulator 160.

With such a structure, the effect of reducing the capacitance of the parasitic capacitance Cp3 can be obtained as in Structure example 2. In addition, when the insulator 181 is provided between the wiring 140 and the upper portion of the conductor 120, the capacitance of the parasitic capacitance Cp4 formed between the wiring 140 and the conductor 120 (the node SN) can be smaller than that in Structure example 2. This corresponds to a reduction in C by increasing the value of the thickness d of the dielectric in the capacitance C=ε×S/d.

In Structure example 2 described above, the distance between the wiring 110 and the upper portion of the conductor 120 and the distance between the wiring 110 and the wiring 140 are greatly affected by the thickness of the insulator 180. Thus, when the distance between the wiring 110 and the upper portion of the conductor 120 is increased, the distance between the wiring 110 (one of the source electrode and the drain electrode) and the wiring 140 (the other of the source electrode and the drain electrode) is also increased. This structure corresponds to an increase in channel length in a vertical transistor. The larger the channel length is, the smaller the current value is; thus, the circuit design flexibility is reduced in some cases.

Meanwhile, the channel length can be adjusted by the thickness of the insulator 180 in Structure example 3. The distance between the wiring 110 and the upper portion of the conductor 120 can be adjusted with the total thickness of the insulator 180 and the insulator 181. Accordingly, the circuit design flexibility can be increased.

### Structure Example 4 of Memory Cell

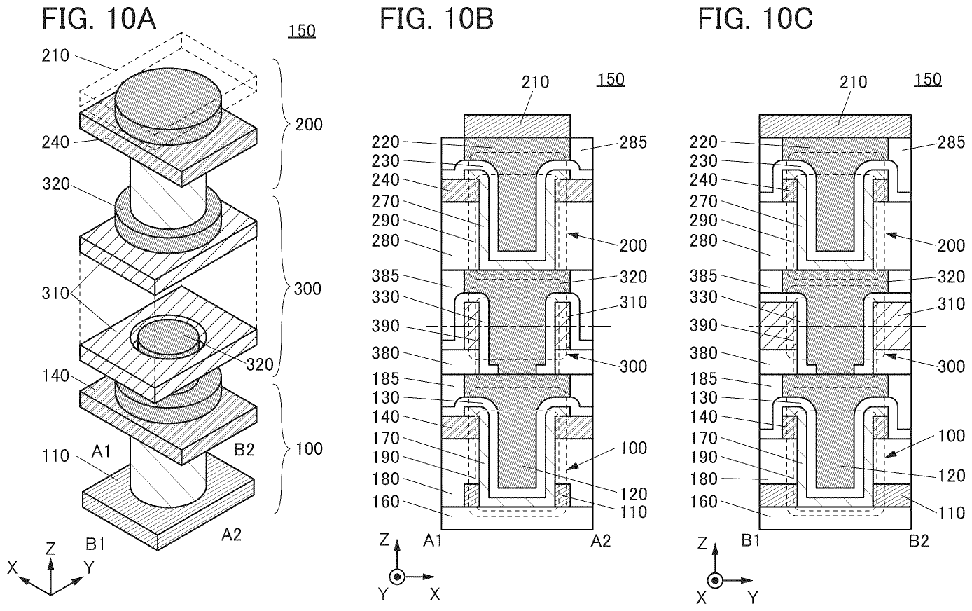

Next, Structure example 4 of the memory cell 150 is described. FIG. 10A is a cross-sectional perspective view illustrating Structure example 4 of the memory cell 150. For clarity, an insulator such as an interlayer film is not illustrated and the wiring 210 is illustrated by dashed lines. The capacitor 300 is divided in the Z direction and a cross section thereof is illustrated.

FIG. 10B is a diagram corresponding to the cross section along the line A1-A2 in FIG. 7A and FIG. 7B. FIG. 10C is a diagram corresponding to the cross section along the line B1-B2 in FIG. 7A and FIG. 7B. In FIG. 10B and FIG. 10C, the dividing position of the capacitor 300 illustrated in FIG. 10A is indicated by a dashed-dotted line. Note that the description of the components common to Structure example 1 is omitted.

Structure example 4 is a structure in which the capacitor 300 is provided between the transistor 100 and the transistor 200 in addition to the structure of Structure example 1. This structure can be applied to the memory cell 150 in the circuit diagram illustrated in FIG. 2C.

The capacitor 300 includes a conductor 320, an insulator 330, and a wiring 310. The conductor 320 functions as one electrode, the insulator 330 functions as a dielectric, and the wiring 310 functions as the other electrode.

An insulator 380 is provided over the transistor 100, and the wiring 310 is provided over the insulator 380. An opening portion 390 penetrating through the wiring 310 and the insulator 380 is provided, and the insulator 330 is provided to cover the opening portion 390. In the bottom portion of the opening portion 390, an opening portion reaching the conductor 120 is provided in the insulator 330. The conductor 320 is provided to fill the opening portion 390 and is in contact with the conductor 120 at the bottom portion of the opening portion 390. An insulator 385 functioning as an interlayer film is provided over the insulator 330 outside the opening portion 390.

The transistor 200 is provided over the insulator 385 and the conductor 320. The oxide semiconductor 270 of the transistor 200 includes a region in contact with the conductor 320 in the bottom portion of the opening portion 290. That is, it can be said that the conductor 320 also includes a region functioning as one of the source electrode and the drain electrode of the transistor 200. In other words, the conductor 320 has a function of a wiring that connects the one of the source electrode and the drain electrode of the transistor 200 and the gate electrode (the conductor 120) of the transistor 100.

Provision of the capacitor 300 increases the capacitance of the node SN, so that potential variation due to capacitive coupling of parasitic capacitances can be inhibited. Thus, the reliability of read data can be increased.

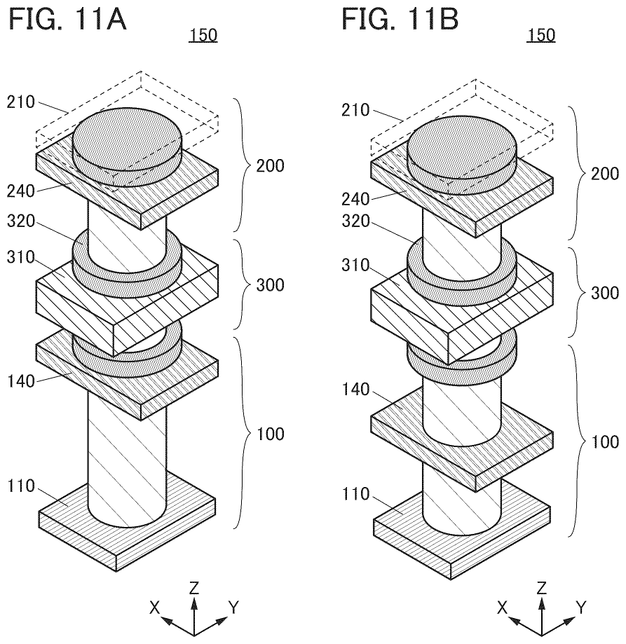

Although FIG. 10A to FIG. 10C illustrate the structure in which the capacitor 300 is added to Structure example 1, the structure in which the capacitor 300 is added to Structure example 2 may be employed as illustrated in the perspective view of FIG. 11A. Alternatively, the structure in which the capacitor 300 is added to Structure example 3 may be employed as illustrated in the perspective view of FIG. 11B.

### Structure Example 5 of Memory Cell

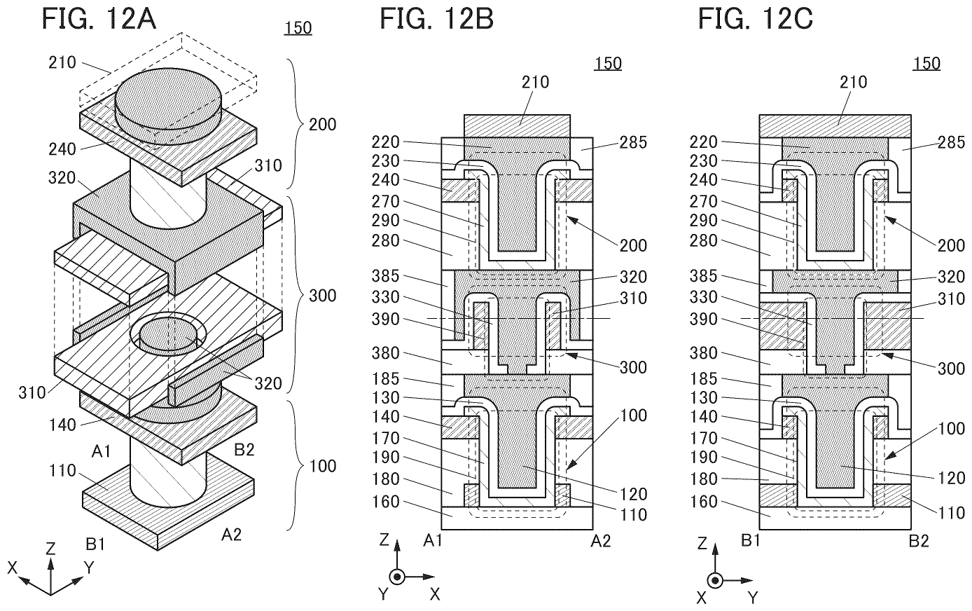

Next, Structure example 5 of the memory cell 150 is described. FIG. 12A is a perspective view illustrating Structure example 5 of the memory cell 150. For clarity, an insulator such as an interlayer film is not illustrated and the wiring 210 is illustrated by dashed lines. The capacitor 300 is divided in the Z direction and a cross section thereof is illustrated.

FIG. 12B is a diagram corresponding to the cross section along the line A1-A2 in FIG. 7A and FIG. 7B. FIG. 12C is a diagram corresponding to the cross section along the line B1-B2 in FIG. 7A and FIG. 7B. In FIG. 12B and FIG. 12C, the dividing position of the capacitor 300 illustrated in FIG. 12A is indicated by a dashed-dotted line. Note that the description of the components common to Structure example 1 and Structure example 4 is omitted.

Structure example 5 is an example in which the capacitor 300 having a structure different from that of Structure example 4 is provided. The insulator 380, the wiring 310, the opening portion 390, and the insulator 330 have the structure similar to that in Structure example 4, and the conductor 320 is formed to cover the wiring 310 and the opening portion 390.

With such a structure, a capacitor in which the wiring 310 serves as one electrode, the insulator 330 serves as a dielectric, and the conductor 320 serves as the other electrode can be formed also outside the opening portion 390. This corresponds to an increase in C by increasing the value of the electrode area S in the capacitance C=ε×S/d.

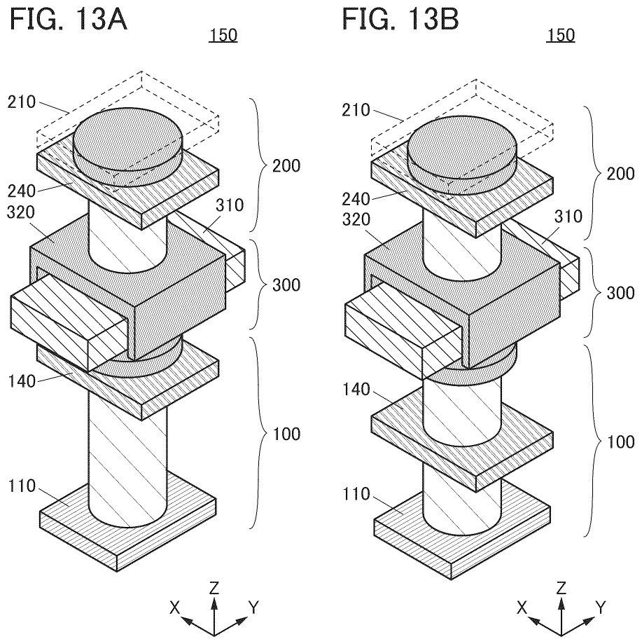

Although FIG. 12A to FIG. 12C illustrate a structure in which the capacitor 300 is added to Structure example 1, the structure in which the capacitor 300 is added to Structure example 2 may be employed as illustrated in the perspective view of FIG. 13A. Alternatively, the structure in which the capacitor 300 is added to Structure example 3 may be employed as illustrated in the perspective view of FIG. 13B.

### Transistors 100 and 200

Next, the details of the transistors 100 and 200 are described. Although the transistor 100 and the transistor 200 are different in the connection mode of the wirings and the like as described above, the transistor 100 and the transistor 200 can be regarded as having basically the same structure in terms of operation, and thus the transistor 200 is described here.

As illustrated in FIG. 7C, FIG. 7D, and the like, the transistor 200 can have a structure including the conductor 120; the wiring 240 over the insulator 280; the oxide semiconductor 270 provided in contact with the top surface of the conductor 120, which is exposed in the opening portion 290, the side surface of the insulator 280 in the opening portion 290, the side surface of the wiring 240 in the opening portion 290, and at least part of the top surface of the wiring 240; the insulator 230 provided in contact with the top surface of the oxide semiconductor 270; and the conductor 220 provided in contact with the top surface of the insulator 230.

At least part of the components of the transistor 200 is placed in the opening portion 290. Here, the bottom portion of the opening portion 290 is also the top surface of the conductor 120, and the side surface of the opening portion 290 is also the side surface of the insulator 280 and the side surface of the wiring 240.

The opening portion 290 has a pillar shape with a substantially circular top surface. With this structure, the memory device can be miniaturized or highly integrated. Note that the side surface of the opening portion 290 is preferably perpendicular to the top surface of the wiring 110.

In order to increase the area where the transistor 200 and the transistor 100 overlap with each other, the top surface shape of the opening portion 290 is preferably the same as or similar to the top surface shape of the opening portion 190 where the transistor 100 is formed.

Portions of the oxide semiconductor 270, the insulator 230, and the conductor 220 that are placed in the opening portion 290 reflect the shape of the opening portion 290. Thus, the oxide semiconductor 270 is provided so as to cover the bottom portion and the side surface of the opening portion 290, the insulator 230 is provided to cover the oxide semiconductor 270, and the conductor 220 is provided so as to be embedded in the depressed portion of the insulator 230, which reflects the shape of the opening portion 290.

Although an example where the opening portion 290 and the conductor 220 are substantially circular in the top view is described in this embodiment, the present invention is not limited thereto. For example, the opening portion 290 and the conductor 220 may each have an elliptical shape, a polygonal shape such as a square shape, or a polygonal shape such as a square shape with rounded corners in the top view. In that case, the maximum width of the opening portion 290 is preferably calculated as appropriate in accordance with the shape of the opening portion 290 in the top view. The maximum width of the conductor 220 is preferably calculated as appropriate in accordance with the shape of the conductor 220 in the top view.

For example, in the case where the opening portion 290 is square in the top view, the maximum width of the opening portion 290 may be the length of a diagonal line of the square. In the case where the conductor 220 is square in the top view, the maximum width of the conductor 220 may be the length of a diagonal line of the square. Alternatively, for example, in the case where the opening portion 290 and the conductor 220 have an elliptical shape, a polygonal shape, or a polygonal shape with rounded corners in the top view, the maximum widths of the opening portion 290 and the conductor 220 may be the diameter of the smallest circle (the minimum bounding circle) including the shape in the top view of the opening portion 290.

The description of the shape of the opening portion 290 can also be applied to the opening portion 190. Furthermore, the description of the shape of the conductor 220 can also be applied to the conductor 120.

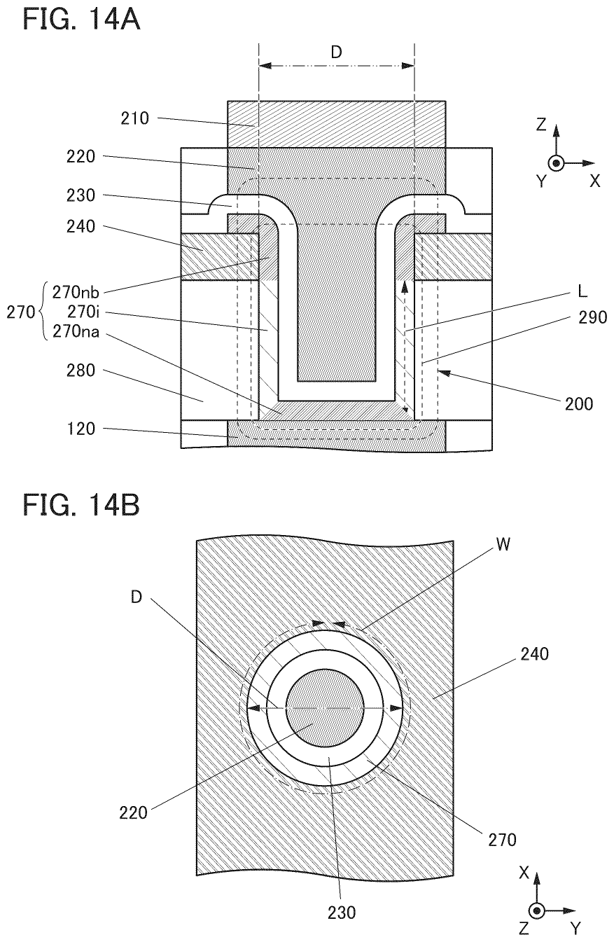

FIG. 14A is an enlarged view of the oxide semiconductor 270 and its vicinity in FIG. 7C and FIG. 7D. FIG. 14B is a cross-sectional view along the XY plane including the wiring 240.

As illustrated in FIG. 14A, the oxide semiconductor 270 includes a region 270i and a region 270na and a region 270nb provided such that the region 270i is sandwiched therebetween.

The region 270na is a region in contact with the conductor 120 in the oxide semiconductor 270. At least part of the region 270na functions as one of the source region and the drain region of the transistor 200. The region 270nb is a region in contact with the wiring 240 in the oxide semiconductor 270. At least part of the region 270nb functions as the other of the source region and the drain region of the transistor 200. As illustrated in FIG. 14B, the wiring 240 is in contact with all the perimeter of the oxide semiconductor 270. Thus, the other of the source region and the drain region of the transistor 200 can be formed along all the perimeter of a portion formed in the same layer as the wiring 240 in the oxide semiconductor 270.

The region 270i is a region positioned between the region 270na and the region 270nb in the oxide semiconductor 270. At least part of the region 270i functions as the channel formation region of the transistor 200. That is, the channel formation region of the transistor 200 is formed in part of the oxide semiconductor 270 that is positioned in a region between the conductor 120 and the wiring 240. It can be said that the channel formation region of the transistor 200 is positioned in a region in contact with the insulator 280 or a region in the vicinity thereof in the oxide semiconductor 270.

The channel length of the transistor 200 is the distance between the source region and the drain region. In other words, the channel length of the transistor 200 is determined by the thickness of the insulator 280 over the conductor 120. In FIG. 14A, a channel length L of the transistor 200 is indicated by a dashed double-headed arrow. The channel length L is a distance between an end portion of a region where the oxide semiconductor 270 and the conductor 120 are in contact with each other and an end portion of a region where the oxide semiconductor 270 and the wiring 240 are in contact with each other in a cross-sectional view. That is, the channel length L corresponds to the length of the side surface of the insulator 280 on the opening portion 290 side in the cross-sectional view.

In a conventional transistor, the channel length is determined by the light exposure limit of photolithography; meanwhile, in the present invention, the channel length can be determined by the thickness of the insulator 280. Thus, the transistor 200 can have an extremely small channel length smaller than or equal to the light exposure limit of photolithography (e.g., smaller than or equal to 60 nm, smaller than or equal to 50 nm, smaller than or equal to 40 nm, smaller than or equal to 30 nm, smaller than or equal to 20 nm, or smaller than or equal to 10 nm, and larger than or equal to 1 nm, or larger than or equal to 5 nm). Accordingly, the transistor 200 can have a higher on-state current and improved frequency characteristics. Thus, a memory device with high operating speed can be provided.

In addition, as described above, the channel formation region, the source region, and the drain region can be formed in the opening portion 290. Thus, the occupation area of the transistor 200 can be reduced as compared with a conventional transistor in which a channel formation region, a source region, and a drain region are provided separately on the XY plane. This allows high integration of the memory device, thereby increasing the storage capacity per unit area.

Such a transistor including the channel formation region along the side surface of the insulator 280 in the opening portion 290 is also referred to as a vertical transistor.

Furthermore, in the XY plane including the channel formation region of the oxide semiconductor 270, as in FIG. 14B, the oxide semiconductor 270, the insulator 230, and the conductor 220 are provided concentrically. Therefore, the side surface of the conductor 220 provided at the center faces the side surface of the oxide semiconductor 270 with the insulator 230 therebetween. That is, in the top view, all the perimeter of the oxide semiconductor 270 serves as the channel formation region. In this case, for example, the channel width of the transistor 200 is determined by the length of the perimeter of the oxide semiconductor 270. In other words, the channel width of the transistor 200 is determined by the maximum width of the opening portion 290 (the maximum diameter in the case where the opening portion 290 is circular in the top view). In FIG. 14A and FIG. 14B, a maximum width D of the opening portion 290 is indicated by a dashed double-dotted double-headed arrow. In FIG. 14B, a channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thicknesses of the oxide semiconductor 270, the insulator 230, and the conductor 220 provided in the opening portion 290. The maximum width D of the opening portion 290 is preferably, for example, larger than or equal to 5 nm, larger than or equal to 10 nm, or larger than or equal to 20 nm and smaller than or equal to 100 nm, smaller than or equal to 60 nm, smaller than or equal to 50 nm, smaller than or equal to 40 nm, or smaller than or equal to 30 nm. In the case where the opening portion 290 is circular in the top view, the maximum width D of the opening portion 290 corresponds to the diameter of the opening portion 290, and the channel width W can be calculated to be “D×π”.

In the memory device of one embodiment of the present invention, the channel length L of the transistor 200 is preferably shorter than at least the channel width W of the transistor 200. The channel length L of the transistor 200 in one embodiment of the present invention is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be substantially circular in the top view, the oxide semiconductor 270, the insulator 230, and the conductor 220 are formed concentrically. This makes the distance between the conductor 220 and the oxide semiconductor 270 substantially uniform, so that a gate electric field can be substantially uniformly applied to the oxide semiconductor 270.

It is preferable that the channel formation region of the transistor including an oxide semiconductor in the semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen has entered (hereinafter sometimes referred to as VoH), which generates an electron serving as a carrier. Thus, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

The source region and the drain region of the transistor including an oxide semiconductor in the semiconductor layer include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 290 is provided such that the side surface of the opening portion 290 is perpendicular to the top surface of the wiring 110 in FIG. 14A and the like, the present invention is not limited thereto. The side surface of the opening portion 290 may have a tapered shape, for example.

The band gap of the metal oxide used as the oxide semiconductor 270 is preferably larger than or equal to 2 eV, further preferably larger than or equal to 2.5 eV. With the use of a metal oxide having a wide band gap for the oxide semiconductor 270, the off-state current of the transistor can be reduced. When a transistor with a low off-state current is used in a memory cell, stored content can be retained for a long time. In other words, such a memory device does not require refresh operation or has extremely low frequency of the refresh operation, which leads to a sufficient reduction in power consumption of the memory device. Note that the frequency of refresh operation in a general DRAM needs to be approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 270, a single layer or stacked layers of any of metal oxides described in the section [Metal oxide] below can be used.

As the oxide semiconductor 270, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is specifically used. Note that a composition in the neighborhood includes the range of ±30 % of an intended atomic ratio. Gallium is preferably used as the element M.

When the metal oxide is deposited by a sputtering method, the above atomic ratio is not limited to the atomic ratio of the deposited of the metal oxide and may be the atomic ratio of a sputtering target used for depositing the metal oxide.

Analysis of the composition of a metal oxide used for the oxide semiconductor 270 can be performed by, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES). Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used to form the metal oxide. In the case where the metal oxide is formed by a sputtering method, the composition of the formed metal oxide may be different from the composition of a sputtering target. In particular, the content percentage of zinc in the formed metal oxide may be reduced to approximately 50 % of that of the sputtering target.

The oxide semiconductor 270 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 270, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is formed. For example, the oxide semiconductor 270 preferably includes a layered crystal that is substantially parallel to the side surface of the opening portion 290, particularly the side surface of the insulator 280. With this structure, the layered crystals of the oxide semiconductor 270 are formed substantially parallel to the channel length direction of the transistor 200, so that the on-state current of the transistor can be increased.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in a CAAC-OS; thus, it can be said that a reduction in electron mobility due to the crystal grain boundary is less likely to occur. Thus, a metal oxide including a CAAC-OS is physically stable. Accordingly, a metal oxide including a CAAC-OS is resistant to heat and has high reliability.

When an oxide having crystallinity, such as CAAC-OS, is used as the oxide semiconductor 270, oxygen extraction from the oxide semiconductor 270 by the source electrode or the drain electrode can be inhibited. This can inhibit oxygen extraction from the oxide semiconductor 270 even when heat treatment is performed; thus, the transistor 200 is stable with respect to high temperatures in a manufacturing process (what is called thermal budget).

The crystallinity of the oxide semiconductor 270 can be analyzed with an X-ray diffraction (XRD) pattern, a transmission electron microscope (TEM) image, or an electron diffraction (ED) pattern, for example. Alternatively, such kinds of analysis methods may be performed in combination.

Although FIG. 7C, FIG. 7D, and the like show that the oxide semiconductor 270 has the single-layer structure, the present invention is not limited thereto. The oxide semiconductor 270 may have a stacked-layer structure of a plurality of oxide layers with different chemical compositions. For example, a structure in which a plurality of kinds of metal oxides selected from the above-described metal oxides are stacked as appropriate may be used.

In the case where the oxide semiconductor 270 has a three-layer structure, the oxide semiconductor 270 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With this structure, the on-state current of the transistor 200 can be increased, and the transistor can have high reliability with small variations.

As the insulator 230, a single layer or stacked layers of any of insulators described in the later-described section [Insulator] can be used. For the insulator 230, silicon oxide or silicon oxynitride can be used, for example. Silicon oxide and silicon oxynitride, which are thermally stable, are preferable.

As the insulator 230, any of materials with high relative dielectric constants, that is, high-k materials, described in the later-described section [Insulator] may be used. For example, hafnium oxide, aluminum oxide, or the like may be used.

The thickness of the insulator 230 is preferably larger than or equal to 0.5 nm and smaller than or equal to 15 nm, further preferably larger than or equal to 0.5 nm and smaller than or equal to 12 nm, still further preferably larger than or equal to 0.5 nm and smaller than or equal to 10 nm. At least part of the insulator 230 has a region with the above-described thickness.

The concentration of impurities such as water and hydrogen in the insulator 230 is preferably reduced. This can inhibit entry of impurities such as water and hydrogen into the channel formation region of the oxide semiconductor 270.

As illustrated in FIG. 7C and FIG. 7D, part of the insulator 230 is positioned outside the opening portion 290, that is, over the wiring 240 and the insulator 280. In this case, the insulator 230 preferably covers the side end portion of the oxide semiconductor 270. This can prevent a short circuit between the conductor 220 and the oxide semiconductor 270. The insulator 230 preferably covers the side end portion of the wiring 240. This can prevent a short circuit between the conductor 220 and the wiring 240.

Although FIG. 7C and FIG. 7D show that the insulator 230 has the single-layer structure, the present invention is not limited thereto. The insulator 230 may have a stacked-layer structure.

As the conductor 220, a single layer or stacked layers of any of conductors described in the later-described section [Conductor] can be used. For example, a conductive material with high conductivity such as tungsten can be used for the conductor 220.

In addition, a conductive material that is less likely to be oxidized, a conductive material having a function of inhibiting diffusion of oxygen, or the like is preferably used for the conductor 220. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 220.

Although FIG. 7C and FIG. 7D show that the conductor 220 has the single-layer structure, the present invention is not limited thereto. The conductor 220 may have a stacked-layer structure.

As the wiring 240, a single layer or stacked layers of any of conductors described in the later-described section [Conductor] can be used. For example, a conductive material with high conductivity such as tungsten can be used for the wiring 240.

A conductive material that is less likely to be oxidized, a conductive material having a function of inhibiting diffusion of oxygen, or the like is preferably used for the wiring 240 like the conductor 220. For example, titanium nitride, tantalum nitride, or the like can be used. This structure can inhibit excessive oxidation of the wiring 240 due to the oxide semiconductor 270.

A structure in which tungsten is stacked over titanium nitride may be used, for example. When tungsten is stacked in this manner, the conductivity of the wiring 240 can be improved.

In the case where the wiring 240 has a structure where a first conductor and a second conductor are stacked, the first conductor may be formed using a conductive material with high conductivity and the second conductor may be formed using a conductive material containing oxygen, for example. When a conductive material containing oxygen is used for the second conductor of the wiring 240 that is in contact with the insulator 230, oxygen in the insulator 230 can be inhibited from diffusing into the first conductor of the wiring 240. For example, tungsten may be used as the first conductor of the wiring 240, and indium tin oxide to which silicon is added may be used as the second conductor of the wiring 240.

When the oxide semiconductor 270 and the conductor 120 are in contact with each other, a metal compound is formed or oxygen vacancies are formed, so that the resistance of the region 270na in the oxide semiconductor 270 is reduced. The reduction in the resistance of the oxide semiconductor 270 in contact with the conductor 120 can reduce the contact resistance between the oxide semiconductor 270 and the conductor 120. Similarly, when the oxide semiconductor 270 and the wiring 240 are in contact with each other, the resistance of the region 270nb in the oxide semiconductor 270 is reduced. Accordingly, the contact resistance between the oxide semiconductor 270 and the wiring 240 can be reduced.

The insulator 280 functions as an interlayer film and thus preferably has a low relative dielectric constant. When a material with a low relative dielectric constant is used for an interlayer film, the capacity of parasitic capacitance generated between wirings can be reduced. As the insulator 280, a single layer or stacked layers of any of insulators each containing a material with low relative dielectric constant described in the later-described section [Insulator] can be used. Silicon oxide and silicon oxynitride are preferable because they are thermally stable.

The concentration of impurities such as water and hydrogen in the insulator 280 is preferably reduced. This can inhibit entry of impurities such as water and hydrogen into the channel formation region of the oxide semiconductor 270.

As the insulator 280, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 270 and oxygen vacancies and VoH can be reduced. Thus, the transistor 200 can have stable electrical characteristics and increased reliability.

As the insulator 280, any of insulators having a function of capturing or fixing hydrogen described in the later-described section [Insulator] may be used. With this structure, hydrogen in the oxide semiconductor 270 can be captured or fixed, so that the concentration of hydrogen in the oxide semiconductor 270 can be reduced. For the insulator 280, magnesium oxide, aluminum oxide, or the like can be used for example.

Although FIG. 7C and FIG. 7D show that the insulator 280 has the single-layer structure, the present invention is not limited thereto. The insulator 280 may have a stacked-layer structure.

### Component Materials of Memory Device

Component materials that can be used for the memory device are described below.

### Substrate

Examples of a substrate where the transistor 100 and the transistor 200 are formed include an insulator substrate, a semiconductor substrate, and a conductor substrate. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate containing silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with a low relative dielectric constant is used for the insulator functioning as an interlayer film, the capacity of parasitic capacitance generated between wirings can be reduced. Thus, a material is preferably selected in accordance with the function of the insulator. Note that the material with a low relative dielectric constant is a material with high dielectric strength.

Examples of the material with high relative dielectric constant (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with low relative dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of the inorganic insulating material with low relative dielectric constant include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used, for example. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the insulator having a barrier property against hydrogen include aluminum oxide, magnesium oxide, hafnium oxide, gallium oxide, indium gallium zinc oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In a metal oxide having an amorphous structure, an oxygen atom has a dangling bond and has a property of capturing or fixing hydrogen with the dangling bond in some cases. Note that such a metal oxide preferably has an amorphous structure, but a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### Conductor

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### Metal Oxide

A metal oxide sometimes has a lattice defect. Examples of the lattice defect include point defects such as an atomic vacancy and an exotic atom, a line defect such as dislocation, a plane defect such as a crystal grain boundary, and a volume defect such as a void. Examples of a factor in generating the lattice defect include deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects for a semiconductor layer of a transistor may cause unstable electrical characteristics of the transistor. Hence, a metal oxide used for a semiconductor layer of a transistor preferably has a small number of lattice defects.

In particular, the electrical characteristics of a transistor including a metal oxide easily vary when oxygen vacancies (V_{O}) and impurities exist in a channel formation region in the metal oxide, which might degrade the reliability. In some cases, a defect (hereinafter sometimes referred to as V_{O}H) that is an oxygen vacancy into which hydrogen in the vicinity of the oxygen vacancy has entered is formed, which generates an electron serving as a carrier. Thus, when the channel formation region in the metal oxide includes oxygen vacancies, the transistor is likely to have normally-on characteristics. Accordingly, oxygen vacancies and impurities are preferably reduced as much as possible in the channel formation region of the metal oxide. In other words, the channel formation region in the metal oxide is preferably an i-type (intrinsic) or substantially i-type region with a reduced carrier concentration.

The kind of a lattice defect that is likely to be present in a metal oxide and the number of lattice defects that are present vary depending on the structure of the metal oxide, a method for forming a film of the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Accordingly, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, the transistor can have high reliability.

For the channel formation region of a transistor, a metal oxide that increases the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS, and the like.

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of a transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide in one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be given as an example.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, variation in electrical characteristics of the transistor can be inhibited, and the reliability of the transistor can be increased.

By increasing the proportion of the number of the element M atoms in the total number of atoms of all the metal elements contained in the metal oxide, oxygen vacancies can be inhibited from being formed in the metal oxide. Accordingly, generation of carriers due to oxygen vacancies is inhibited, which can make the off-state current of the transistor low. Furthermore, variation in electrical characteristics of the transistor can be inhibited, and the reliability of the transistor can be increased.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the deposition method of the metal oxide in one embodiment of the present invention, a metal oxide having the layered crystal structure is easily formed.

Examples of the ALD method include a thermal ALD method, in which a precursor and a reactant react with each other only by thermal energy, and a plasma ALD (PEALD: Plasma Enhanced ALD) method, in which a reactant excited by plasma is used.

The ALD method enables atomic layers to be deposited one by one, and has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS. The deposition method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, an ALD method is a deposition method that enables favorable step coverage almost regardless of the shape of an object. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

In the ALD method, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is omitted. Thus, the productivity of the memory device can be increased in some cases.

### Transistor Including Metal Oxide

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When the metal oxide (oxide semiconductor) of one embodiment of the present invention is used for a transistor, a transistor with high field-effect mobility can be achieved. In addition, the transistor can have high reliability. Furthermore, a miniaturized or highly integrated transistor can be achieved. For example, a transistor with a channel length larger than or equal to 2 nm and smaller than or equal to 30 nm can be manufactured.

An oxide semiconductor having a low carrier concentration is preferably used for a channel formation region of a transistor. For example, the carrier concentration of an oxide semiconductor in the channel formation region is lower than or equal to 1×10¹⁸ cm ³, preferably lower than or equal to 1×10¹⁷ cm ³, further preferably lower than or equal to 1×10¹⁵ cm ³, still further preferably lower than or equal to 1×10¹³ cm ³, yet still further preferably lower than or equal to 1×10¹¹ cm ³, yet still further preferably lower than 1×10¹⁰ cm ³, and higher than or equal to 1×10⁻⁹ cm ³. In order to reduce the carrier concentration in an oxide semiconductor, the impurity concentration in the oxide semiconductor is reduced so that the density of defect states is reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic% can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, an OS transistor includes an oxide semiconductor that is a semiconductor material having a large band gap, and thus can inhibit the short-channel effect. In other words, the OS transistor is a transistor in which the short-channel effect does not appear or hardly appears.

Note that the short-channel effect refers to degradation of electrical characteristics which becomes apparent along with miniaturization of a transistor (a decrease in channel length). Specific examples of the short-channel effect include a decrease in the threshold voltage, an increase in subthreshold swing value (sometimes also referred to as S value), and an increase in leakage current. Here, the S value means the amount of change in the gate voltage in the subthreshold region by which the drain current is changed by one order of magnitude at a constant drain voltage.

The characteristic length is widely used as an indicator of resistance to the short-channel effect. The characteristic length is an indicator of curving of a potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to larger than or equal to 0.1 eV and smaller than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

The OS transistor with the above structure can have favorable electrical characteristics even when a memory device is miniaturized or highly integrated. For example, favorable electrical characteristics can be obtained even when the OS transistor has a channel length or a gate length smaller than or equal to 20 nm, smaller than or equal to 15 nm, smaller than or equal to 10 nm, smaller than or equal to 7 nm, or smaller than or equal to 6 nm and larger than or equal to 1 nm, larger than or equal to 3 nm, or larger than or equal to 5 nm. By contrast, it is sometimes difficult for the Si transistor to have a gate length less than or equal to 20 nm or less than or equal to 15 nm because of the appearance of the short-channel effect. Thus, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be higher than or equal to 50 GHz, preferably higher than or equal to 100 GHz, further preferably higher than or equal to 150 GHz in a room temperature environment, for example.

As described above, the OS transistor has effects superior to those of the Si transistor, such as a low off-state current and capability of having a short channel length.

### Impurity in Metal Oxide

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Thus, the nitrogen concentration in the channel formation region of the oxide semiconductor that is obtained by SIMS is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### Other Semiconductor Materials

The oxide semiconductor 270 can be rephrased as a semiconductor layer including the channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as the semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

According to one embodiment of the present invention, a novel transistor, a novel semiconductor device, and a novel memory device can be provided. A memory device that can be miniaturized or highly integrated can be provided. Alternatively, a memory device with favorable frequency characteristics can be provided. Alternatively, a memory device with a high operation speed can be provided. A memory device with high reliability can be provided. A memory device with low power consumption can be provided. A memory device including a transistor with a high on-state current can be provided. A memory device with a small variation in transistor characteristics can be provided. A memory device with favorable electrical characteristics can be provided.

The configuration, structure, method, and the like described in this embodiment can be used in combination as appropriate with the configurations, structures, methods, and the like described in the other embodiments and the like.

### Embodiment 2

In this embodiment, a structure example of the memory device of one embodiment of the present invention will be described with reference to drawings.

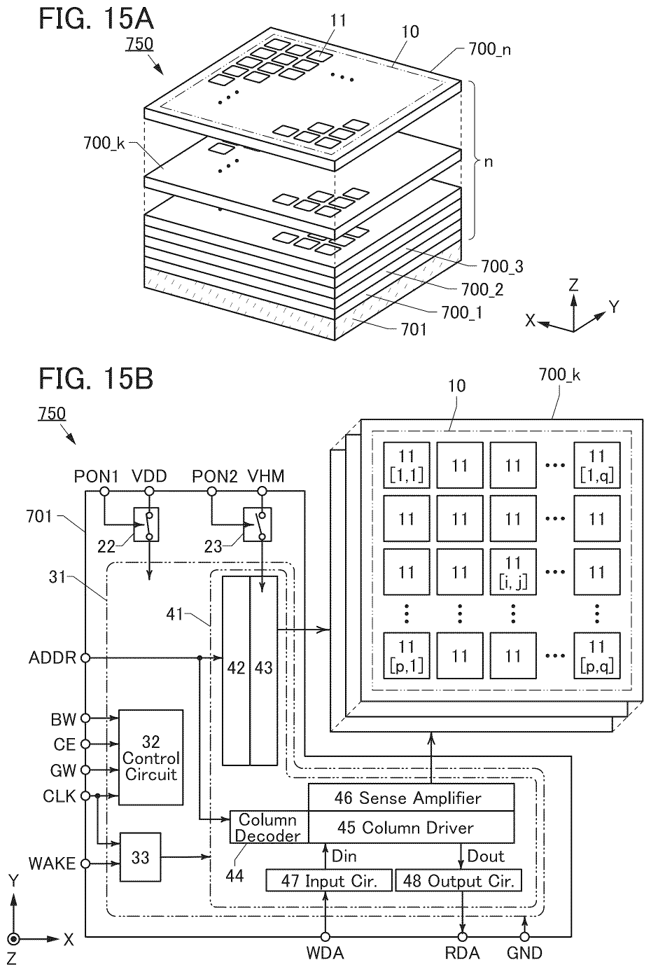

FIG. 15A is a schematic perspective view of the memory device of one embodiment of the present invention. FIG. 15B is a block diagram of the memory device of one embodiment of the present invention.

A memory device 750 illustrated in FIG. 15A and FIG. 15B includes a driver circuit layer 701 and n memory layers 700 (n is an integer greater than or equal to 1). Each of the memory layers 700 includes a memory cell array 10. The memory cell array 10 includes a plurality of memory cells 11.

The n memory layers 700 are provided over the driver circuit layer 701. Provision of the n memory layers 700 over the driver circuit layer 701 can reduce the area occupied by the memory device 750. Furthermore, memory capacity per unit area can be increased.

In this embodiment and the like, the first memory layer 700 is referred to as a memory layer 700_1, the second memory layer 700 is referred to as a memory layer 700_2, and the third memory layer 700 is referred to as a memory layer 700_3. Furthermore, the k-th (k is an integer greater than or equal to 1 and less than or equal to n) memory layer 700 is referred to as a memory layer 700_k, and the n-th memory layer 700 is referred to as a memory layer 700_n. Note that in this embodiment and the like, the simple term “memory layer 700” is sometimes used in the case of describing matters related to all the n memory layers 700 or matters common to the n memory layers 700.

The driver circuit layer 701 includes a PSW 22 (power switch), a PSW 23, and a peripheral circuit 31. The peripheral circuit 31 includes a peripheral circuit 41, a control circuit 32, and a voltage generation circuit 33.

In the memory device 750, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 750. For example, the control circuit performs a logical operation on the signal CE, the signal GW, and the signal BW to determine an operation mode (e.g., a writing operation or a reading operation) of the memory device 750. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 11. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 11, a function of reading data from the memory cells 11, a function of retaining the read data, and the like. The column driver 45 has a function of selecting a wiring WBL (write bit line) and a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 11. Data (Dout) read from the memory cells 11 by the column driver 45 is output to the output circuit 48. The output circuit 48 has a function of retaining Dout. In addition, the output circuit 48 has a function of outputting Dout to the outside of the memory device 750. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 750, a high power supply voltage is VDD and a low power supply voltage is GND (a ground potential). In addition, VHM is a high power supply voltage used to set a word line at the high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 15B but can be more than one. In that case, a power switch is provided for each power domain.

A structure example of the n memory layers 700 will be described. Each of the n memory layers 700 includes the memory cell array 10. The memory cell array 10 includes the plurality of memory cells 11. FIG. 15A and FIG. 15B illustrate an example in which the memory cell array 10 includes the plurality of memory cells 11 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 15B, the memory cell 11 provided in the first row and the first column is referred to as a memory cell 11[1,1], and the memory cell 11 provided in the p-th row and the q-th column is referred to as a memory cell 11[p,q]. In addition, the memory cell 11 provided in the i-th row and the j-th column (i is an integer greater than or equal to 1 and less than or equal to p, and j is an integer greater than or equal to q) is indicated as a memory cell 11[i,j].

As a circuit structure example of the memory cells 11, the structure described in the above embodiment (the memory cell 150) can be employed.

In the case where the memory layers 700 are stacked, it is preferable to arrange the wiring WBL and the wiring RBL in a direction perpendicular to the substrate surface. When the wiring WBL and the wiring RBL are provided in the direction perpendicular to the substrate surface, the signal transmission distance from the sense amplifier connected to the wiring WBL and the wiring RBL can be shortened and the resistance and parasitic capacitance of the wiring WBL and the wiring RBL can be significantly reduced. Thus, power consumption and signal delays can be reduced.

The configuration, structure, method, and the like described in this embodiment can be used in combination as appropriate with the configurations, structures, methods, and the like described in the other embodiments, an example, and the like.

### Embodiment 3

In this embodiment, electronic components, electronic devices, a large computer, space equipment, and a data center (also referred to as DC) in which the memory device described in the above embodiments can be used will be described. Electronic components, electronic devices, a large computer, space equipment, and a data center in which the memory device of one embodiment of the present invention is used are effective in improving performance, e.g., reducing power consumption.

### Electronic Component

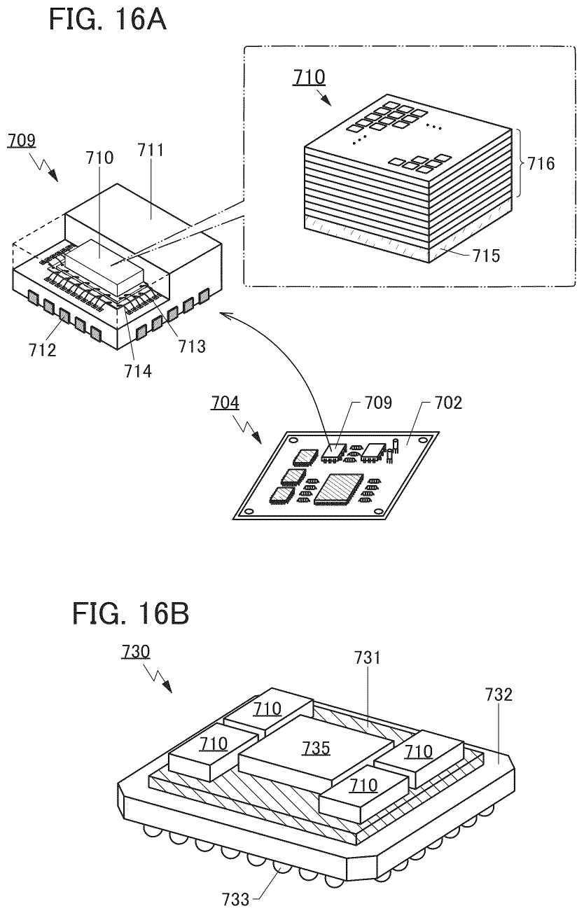

FIG. 16A is a perspective view of a substrate (a mounting board 704) mounted with an electronic component 709. The electronic component 709 illustrated in FIG. 16A includes a memory device 710 in a mold 711. FIG. 16A omits illustrations of some parts to show the inside of the electronic component 709. The electronic component 709 includes a land 712 outside the mold 711. The land 712 is electrically connected to an electrode pad 713, and the electrode pad 713 is electrically connected to the memory device 710 through a wire 714. The electronic component 709 is mounted on a printed circuit board 702, for example. A plurality of such electronic components are combined and electrically connected to each other on the printed circuit board 702, which forms the mounting board 704.

The memory device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

In addition, with the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. The monolithic stacked-layer structure of the plurality of memory cell arrays can improve the bandwidth of the memory and/or the access latency of the memory. Note that the bandwidth refers to the data transfer amount per unit time, and the access latency refers to time between data access and start of data transmission. In the case where the memory layer 716 is formed using Si transistors, it is difficult to obtain the monolithic stacked-layer structure as compared with the case where the memory layer 716 is formed using OS transistors. Thus, the OS transistors are superior to the Si transistors in the monolithic stacked-layer structure.

The memory device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 16B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of memory devices 710 are provided on the interposer 731.

The electronic component 730 using the memory devices 710 as a high bandwidth memory (HBM) is shown as an example. As the memory device 735, an integrated circuit such as a CPU (Central Processing Unit), a GPU (Graphics Processing Unit), or an FPGA (Field Programmable Gate Array) can be used.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in a silicon interposer, a TSV can also be used as the through electrode.

In an HBM, many wirings need to be connected to achieve wide memory bandwidth. Thus, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer does not easily occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (radiator plate) may be provided to overlap with the electronic component 730. In the case of providing a heat sink, the levels of integrated circuits provided on the interposer 731 are preferably equal to each other. In the electronic component 730 of this embodiment, the levels of the memory device 710 and the semiconductor device 735 are preferably equal to each other, for example.

An electrode 733 may be provided on the bottom portion of the package substrate 732 to mount the electronic component 730 on another substrate. FIG. 16B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### Electronic Device

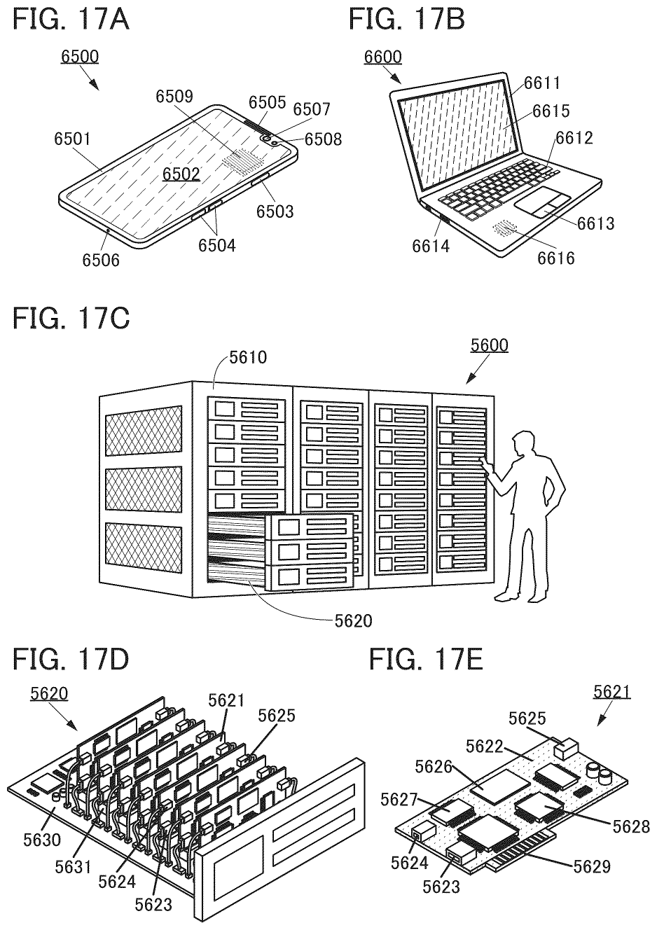

Next, a perspective view of an electronic device 6500 is illustrated in FIG. 17A. The electronic device 6500 illustrated in FIG. 17A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The memory device of one embodiment of the present invention can be employed for the display portion 6502, the control device 6509, or the like.

An electronic device 6600 illustrated in FIG. 17B is an information terminal that can be used as a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The memory device of one embodiment of the present invention can be employed for the display portion 6615, the control device 6616, or the like. Note that the memory device of one embodiment of the present invention is preferably used for the control device 6509 and the control device 6616, in which case power consumption can be reduced.

### Large Computer

Next, FIG. 17C is a perspective view of a large computer 5600. In the large computer 5600 illustrated in FIG. 17C, a plurality of rack mount computers 5620 are stored in a rack 5610. Note that the large computer 5600 may also be referred to as a supercomputer.

The computer 5620 can have a structure in the perspective view illustrated in FIG. 17D, for example. In FIG. 17D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 17E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 17E illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected.

The semiconductor device 5627 includes a plurality of terminals, and when the terminals are reflow-soldered, for example, to wirings of the board 5622, the semiconductor device 5627 and the board 5622 can be electrically connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be electrically connected. An example of the semiconductor device 5628 is a memory device. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### Space Equipment

The memory device of one embodiment of the present invention can be suitably used as space equipment such as equipment that processes and stores information.

The memory device of one embodiment of the present invention can include an OS transistor. Variation in electrical characteristics of the OS transistor due to exposure to radiation is small. That is, the OS transistor is highly resistant to radiation, and thus can be suitably used in an environment where radiation can enter. For example, the OS transistor can be suitably used in outer space.

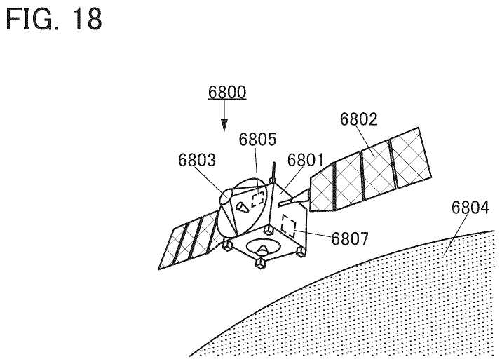

FIG. 18 illustrates an artificial satellite 6800 as an example of space equipment. The artificial satellite 6800 includes a body 6801, a solar panel 6802, an antenna 6803, a secondary battery 6805, and a control device 6807. In FIG. 18, a planet 6804 in outer space is illustrated. Note that outer space refers to, for example, space at an altitude greater than or equal to 100 km, and outer space described in this specification may include thermosphere, mesosphere, and stratosphere.

Although not illustrated in FIG. 18, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the memory device of one embodiment of the present invention is suitably used for the control device 6807. Variation in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The memory device of one embodiment of the present invention can be suitably used for space equipment, such as a spacecraft, a space capsule, or a space probe, for example.

As described above, the OS transistor has excellent effects of achieving a wide memory bandwidth and being highly resistant to radiation as compared with the Si transistor.

### Data Center

The memory device of one embodiment of the present invention can be suitably used for a storage system in a data center, for example. Long-term data management, such as a guarantee for data immutability, is required for the data center. The long-term management of data needs an increase in building size owing to installation of storages and servers for storing an enormous amount of data, stable electric power for data retention, cooling equipment necessary for data retention, and the like.

With use of the memory device of one embodiment of the present invention for the storage system used in the data center, electric power required for data retention can be reduced and the size of a memory device retaining data can be downsized. Accordingly, downsizing of the storage system, downsizing of a power source for data retention, downscaling of cooling equipment, and the like can be achieved. This can reduce the space of the data center.

Since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention enables a data center that operates stably even in a high-temperature environment. Thus, the reliability of the data center can be increased.

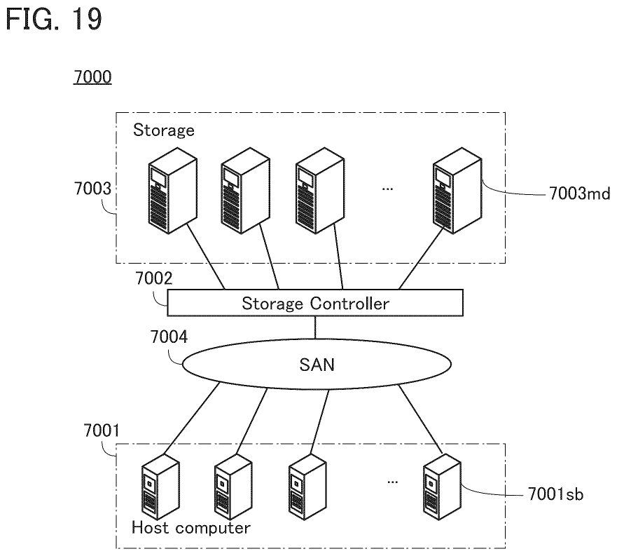

FIG. 19 illustrates a storage system that can be used in a data center. A storage system 7000 illustrated in FIG. 19 includes a plurality of servers 7001sb as a host 7001 (indicated as “Host Computer” in the diagram). In addition, the storage system 7000 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the memory device of one embodiment of the present invention for one or more selected from an electronic component, an electronic device, a large computer, space equipment, and a data center will produce an effect of reducing power consumption. Although demand for energy will increase with increasing performance and integration degree of memory devices, the use of the memory device of one embodiment of the present invention can thus reduce the emission amount of greenhouse gas typified by carbon dioxide (CO₂). The memory device of one embodiment of the present invention can be effectively used as one of the global warming countermeasures because of its low power consumption.

The configuration, structure, method, and the like described in this embodiment can be used in combination as appropriate with the configurations, structures, methods, and the like described in the other embodiments and the like.

### REFERENCE NUMERALS

11: memory cell, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 100: transistor, 110: wiring, 120: conductor, 130: insulator, 140: wiring, 150: memory cell, 160: insulator, 170: oxide semiconductor, 180: insulator, 181: insulator, 185: insulator, 190: opening portion, 200: transistor, 210: wiring, 220: conductor, 230: insulator, 240: wiring, 270i: region, 270na: region, 270nb: region, 270: oxide semiconductor, 280: insulator, 285: insulator, 290: opening portion, 300: capacitor, 310: wiring, 320: conductor, 330: insulator, 380: insulator, 385: insulator, 390: opening portion, 700_1: memory layer, 700_2: memory layer, 700_3: memory layer, 700_k: memory layer, 700_n: memory layer, 700: memory layer, 701: driver circuit layer, 702: printed circuit board, 704: mounting board, 709: electronic component, 710: memory device, 711: mold, 712: land, 713: electrode pad, 714: wire, 715: driver circuit layer, 716: memory layer, 730: electronic component, 731: interposer, 732: package substrate, 733: electrode, 735: semiconductor device, 750: memory device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A memory device comprising:
a memory cell, a first wiring, a second wiring, and a third wiring,
wherein the memory cell comprises a first transistor and a second transistor,
wherein the second transistor is positioned above the first transistor,
wherein the first transistor comprises a first semiconductor, a first insulator, and a first conductor,
wherein the first semiconductor comprises a region formed positioned along a side surface of a first opening portion penetrating through the first wiring, a second insulator, and the second wiring,
wherein the first insulator comprises a region being in contact with the first semiconductor and covering the first opening portion,
wherein the first conductor is provided positioned to be in contact with the first insulator and fill the first opening portion,
wherein the second transistor comprises a second semiconductor,
wherein the second semiconductor comprises a region provided positioned along a side surface of a second opening portion penetrating through a third insulator and the third wiring, and
wherein the second semiconductor comprises a region in contact with the first conductor in a bottom portion of the second opening portion.

2. The memory device according to claim 1,
wherein the second wiring is positioned over the second insulator, and wherein the second insulator is positioned over the first wiring.

3. The memory device according to claim 1,
wherein the second transistor comprises a fourth insulator and a second conductor,
wherein the fourth insulator comprises a region in contact with the second semiconductor and covering the second opening portion, and
wherein the second conductor is positioned to be in contact with the fourth insulator and fill the second opening portion.

4. The memory device according to claim 1,
wherein the third wiring is positioned over the third insulator, and
wherein the third insulator is positioned over the first conductor.

5. The memory device according to claim 1,
wherein the first wiring comprises a region configured to be as one of a source electrode and a drain electrode of the first transistor,
wherein the second wiring comprises a region configured to be as the other of the source electrode and the drain electrode of the first transistor,
wherein the third wiring comprises a region configured to be as one of a source electrode and a drain electrode of the second transistor, and
wherein the first conductor comprises a region configured to be as a gate electrode of the first transistor and a region configured to be as the other of the source electrode and the drain electrode of the second transistor.

6. A memory device comprising:
a memory cell, a first wiring, a second wiring, and a third wiring,
wherein the memory cell comprises a first transistor and a second transistor,
wherein the second transistor is positioned above the first transistor,
wherein the first transistor comprises a first semiconductor, a first insulator, and a first conductor,
wherein the first semiconductor comprises a region positioned along a side surface of a first opening portion penetrating through the first wiring, a second insulator, the second wiring, and a third insulator,
wherein the first insulator comprises a region being in contact with the first semiconductor and covering the first opening portion,
wherein the first conductor is positioned to be in contact with the first insulator and fill the first opening portion,
wherein the second transistor comprises a second semiconductor,
wherein the second semiconductor comprises a region positioned along a side surface of a second opening portion penetrating through a fourth insulator and the third wiring, and
wherein the second semiconductor comprises a region in contact with the first conductor in a bottom portion of the second opening portion.

7. The memory device according to claim 6,
wherein the third insulator is positioned over the second wiring,
wherein the second wiring is positioned over the second insulator, and
wherein the second insulator is positioned over the first wiring.

8. The memory device according to claim 6,
wherein the second transistor comprises a fifth insulator and a second conductor,
wherein the fifth insulator comprises a region being in contact with the second semiconductor and covering the second opening portion, and
wherein the second conductor is positioned to be in contact with the fifth insulator and fill the second opening portion.

9. The memory device according to claim 6,
wherein the third wiring is positioned over the fourth insulator, and
wherein the fourth insulator is positioned over the first conductor.

10. The memory device according to claim 6,
wherein the first wiring comprises a region configured to be as one of a source electrode and a drain electrode of the first transistor,
wherein the second wiring comprises a region configured to be as the other of the source electrode and the drain electrode of the first transistor,
wherein the third wiring comprises a region configured to be as one of a source electrode and a drain electrode of the second transistor, and
wherein the first conductor comprises a region configured to be gate electrode of the first transistor and a region configured to be as the other of the source electrode and the drain electrode of the second transistor.

11. A memory device comprising:
a memory cell, a first wiring, a second wiring, a third wiring, and a fourth wiring,
wherein the memory cell comprises a first transistor, a second transistor, and a capacitor,
wherein the capacitor is positioned between the first transistor and the second transistor,
wherein the first transistor comprises a first semiconductor, a first insulator, and a first conductor,
wherein the first semiconductor comprises a region positioned along a side surface of a first opening portion penetrating through the first wiring, a second insulator, and the second wiring,
wherein the first insulator comprises a region being in contact with the first semiconductor and covering the first opening portion,
wherein the first conductor is positioned to be in contact with the first insulator and fill the first opening portion,
wherein the capacitor comprises a third insulator and a second conductor,
wherein the third insulator comprises a region positioned along a side surface of a second opening portion penetrating through a fourth insulator and the third wiring,
wherein the second conductor is positioned to be in contact with the third insulator and fill the second opening portion,
wherein the second conductor comprises a region in contact with the first conductor in a bottom portion of the second opening portion,
wherein the second transistor comprises a second semiconductor,
wherein the second semiconductor comprises a region positioned along a side surface of a third opening portion penetrating through a fifth insulator and the fourth wiring, and
wherein the second semiconductor comprises a region in contact with the second conductor in a bottom portion of the third opening portion.

12. The memory device according to claim 11,
wherein the second wiring is positioned over the second insulator,
wherein the second insulator is positioned over the first wiring, and
wherein the third wiring is positioned over the fourth insulator.

13. The memory device according to claim 11,
wherein the second transistor comprises a sixth insulator and a third conductor,
wherein the sixth insulator comprises a region being in contact with the second semiconductor and covering the third opening portion, and
wherein the third conductor is positioned to be in contact with the sixth insulator and fill the third opening portion.

14. The memory device according to claim 11,
wherein the fourth wiring is positioned over the fifth insulator, and
wherein the fifth insulator is positioned over the second conductor.

15. The memory device according to claim 11,
wherein the first wiring comprises a region configured to be as one of a source electrode and a drain electrode of the first transistor,
wherein the second wiring comprises a region configured to be as the other of the source electrode and the drain electrode of the first transistor,
wherein the third wiring comprises a region configured to be as one electrode of the capacitor,
wherein the fourth wiring comprises a region configured to be as one of a source electrode and a drain electrode of the second transistor,
wherein the first conductor comprises a region configured to be as a gate electrode of the first transistor, and
wherein the second conductor comprises a region configured to be as the other electrode of the capacitor and a region configured to be as the other of the source electrode and the drain electrode of the second transistor.

16. The memory device according to claim 1,
wherein each of the first semiconductor and the second semiconductor is an oxide semiconductor, and
wherein the oxide semiconductor comprises any one or more selected from In, Ga, and Zn.

17. The memory device according to claim 6,
wherein each of the first semiconductor and the second semiconductor is an oxide semiconductor, and
wherein the oxide semiconductor comprises any one or more selected from In, Ga, and Zn.

18. The memory device according to claim 11,
wherein each of the first semiconductor and the second semiconductor is an oxide semiconductor, and
wherein the oxide semiconductor comprises any one or more selected from In, Ga, and Zn.
